(19) United States
(12) Patent Application Publication
(10) Pub. No.: US 2026/0033070 A1
(43) Pub. Date: Jan. 29, 2026

(54) DISPLAY DEVICE

(71) Applicants: LG ELECTRONICS INC., Seoul (KR); LG DISPLAY CO., LTD., Seoul (KR)

(72) Inventors: Jaewon CHANG, Seoul (KR); Wonseok CHOI, Seoul (KR)

(73) Assignees: LG ELECTRONICS INC., Seoul (KR); LG DISPLAY CO., LTD., Seoul (KR)

(21) Appl. No.: 18/996,782

(22) PCT Filed: Jul. 20, 2022
(86) PCT No.: PCT/KR2022/010619

§ 371 Date: Jan. 17, 2025

(51) Int. Cl. H10H 29/49; H10H 29/39

(52) U.S. Cl. CPC H10H 29/49; H10H 29/39

(57) ABSTRACT

A display device may include a first sub-pixel including a pair of first assembly wirings, a first assembly hole, and a first semiconductor light emitting device in the first assembly hole, a second sub-pixel including a pair of second assembly wirings, a second assembly hole, and a second semiconductor light emitting device in the second assembly hole, and a third sub-pixel including a pair of third assembly wirings, a third assembly hole, and a third semiconductor light emitting device in the third assembly hole. The first assembly hole, the second assembly hole, and the third assembly hole may have different sizes. The first semiconductor light emitting device may include a first ring electrode. The first assembly wiring may include a first-first assembly wiring and a first-second assembly wiring having a first gap region at an edge of the first assembly hole. The first ring electrode of the first semiconductor light emitting device may disposed in the first gap region.

### TECHNICAL FIELD

The embodiment relates to a display device.

### BACKGROUND ART

Large-area displays include liquid crystal displays (LCDs), OLED displays, and micro-LED displays.

A micro-LED display is a display that uses micro-LEDs, which are semiconductor light emitting devices with a diameter or cross-sectional area of 100 μm or less, as display elements.

Since a micro-LED display uses micro-LEDs, which are semiconductor light emitting devices, as display elements, it has excellent performance in many characteristics such as contrast ratio, response speed, color reproducibility, viewing angle, brightness, resolution, life, luminous efficiency, and luminance.

In particular, a micro-LED display has the advantage of being able to freely adjust the size or resolution by separating and combining the screen in a modular manner, and the advantage of being able to implement a flexible display.

However, since large micro-LED displays require millions or more micro-LEDs, there is a technical problem that makes it difficult to quickly and accurately transfer micro-LEDs to the display panel.

Recently developed transfer technologies include a pick and place process, a laser lift-off method, and a self-assembly method.

Among these, the self-assembly method is a method in which semiconductor light emitting devices find their assembly positions in a fluid, and the self-assembly method is advantageous for implementing large-screen display devices.

However, research on the technology for manufacturing displays through self-assembly of micro-LEDs is still insufficient.

In particular, in the case of rapidly transferring millions or more semiconductor light emitting devices to a large display in the conventional technology, the transfer speed may be improved, but the transfer error rate can increase, which has a technical problem of lowering the transfer yield.

In related technology, a self-assembly transfer process using dielectrophoresis (DEP) is adopted, but there is a problem that the self-assembly rate is low due to a non-uniformity of the DEP force.

FIG. 1 illustrates a situation where color mixing defects occur in a non-published internal technology.

As shown in FIG. 1, a plurality of semiconductor light emitting devices (7 to 9) are assembled into a plurality of assembly holes (4 to 6) on a substrate using a self-assembly process.

A DEP force may be formed between a pair of assembly wirings (1, 2) in each assembly hole (4 to 6) by a voltage applied to a pair of assembly wirings (1, 2).

For self-assembly, a plurality of semiconductor light emitting devices (7 to 9) that emit different light are introduced into a fluid, and the plurality of semiconductor light emitting devices (7 to 9) are moved in the fluid by a magnet.

The plurality of semiconductor light emitting devices (7 to 9) are assembled into each assembly hole (4 to 6) by the DEP force during moving.

Meanwhile, if the sizes of the plurality of assembly holes (4 to 6) are the same, and the sizes of the plurality of semiconductor light emitting devices (7 to 9) are the same as the sizes of the plurality of assembly holes (4 to 6), the plurality of semiconductor light emitting devices (7 to 9) may not be assembled into the predetermined positions. For example, even though the first semiconductor light emitting device (7) should be assembled into the first assembly hole (4), the second semiconductor light emitting device (8) or the third semiconductor light emitting device (9) can be assembled into the first assembly hole (4), causing a color mixing defect.

In order to prevent such a color mixing defect, as illustrated in FIG. 1, the sizes of the plurality of assembly holes (4 to 6) are different from each other, and the plurality of semiconductor light emitting devices (7 to 9) are also different from each other, but correspond to the sizes of each of the plurality of assembly holes (4 to 6). In this case, most of the semiconductor light emitting devices (7 to 9) are assembled at the designated location.

However, there is a problem that a small semiconductor light emitting device (9) is frequently assembled into a large assembly hole (4), and color mixing defects still occur. In other words, a small semiconductor light emitting device (9) may be easily assembled into a large assembly hole (4), and thus color mixing defects are highly likely to occur. In addition, the DEP force formed in a pair of assembly wirings (1, 2) located in a large assembly hole (4) strongly affects the entire area of the small semiconductor light emitting device (9), so that once the semiconductor light emitting device (9) is assembled into the assembly hole (4), it does not escape from the assembly hole (4), and thus the color mixing defects may not be resolved during the self-assembly process.

Meanwhile, as illustrated in FIG. 1, since the DEP force may be non-uniform along the X-axis direction within the assembly hole (4 to 6) and strongly acts only along the center line of the semiconductor light emitting device (7 to 9) along the length direction along the Y-axis direction, the semiconductor light emitting device (7 to 9) may not be stably assembled within the assembly hole (4 to 6). That is, since the DEP force does not act on the edge of the semiconductor light emitting device (7 to 9), a defect occurs in which the semiconductor light emitting device (7 to 9) is assembled into the assembly hole (4 to 6) in a twisted or tilted state.

In addition, even if the semiconductor light emitting device (7 to 9) is assembled into the assembly hole (4 to 6), since the DEP force does not act on the edge of the semiconductor light emitting device (7 to 9), there is a problem in which the semiconductor light emitting device (7 to 9) may not be fixed within the assembly hole (4 to 6) and may be detached.

### DISCLOSURE

### Technical Problem

The embodiment aims to solve the above-mentioned problem and other problems.

Another object of the embodiment is to provide a display device capable of preventing color mixing defects.

In addition, another object of the embodiment is to provide a display device capable of preventing assembly defects.

In addition, another object of the embodiment is to provide a display device capable of preventing detachment of a pre-assembled semiconductor light emitting device.

The technical problem of the embodiment is not limited to what is described in this item, and may include what may be understood through the description of the invention.

### Technical Solution

In order to achieve the above or other objects, according to one aspect of the embodiment, a display device may include a first sub-pixel including a pair of first assembly wirings, a first assembly hole, and a first semiconductor light emitting device in the first assembly hole; a second sub-pixel including a pair of second assembly wirings, a second assembly hole, and a second semiconductor light emitting device in the second assembly hole; and a third sub-pixel including a pair of third assembly wirings, a third assembly hole and a third semiconductor light emitting device in the third assembly hole; wherein the first assembly hole, the second assembly hole and the third assembly hole may have different sizes from each other, and the first semiconductor light emitting device may include a first ring electrode; and the first assembly wiring may include a first-first assembly wiring and a first-second assembly wiring having a first gap area at an edge of the first assembly hole, and the first ring electrode of the first semiconductor light emitting device is disposed in the first gap area.

The second semiconductor light emitting device may include a second ring electrode; and the pair of second assembly wirings may include a second-first assembly wiring and a second-second assembly wiring having a second gap region at an edge of the second assembly hole, and the second ring electrode of the second semiconductor light emitting device may be positioned in the second gap region. An outer diameter of the first ring electrode may be larger than an outer diameter of the second ring electrode.

The third semiconductor light emitting device may include a plate electrode; and the pair of third assembly wirings may include a third-first assembly wiring and a third-second assembly wiring having a third gap region at an edge of the third assembly hole, and the third ring electrode of the third semiconductor light emitting device may be positioned in the third gap region. A diameter of the plate electrode may be smaller than an inner diameter of the second ring electrode.

The first ring electrode, the second ring electrode, and the plate electrode may not be vertically overlapped each other.

The first-first assembly wiring, the second-first assembly wiring, and the third-first assembly wiring may each include a main electrode; and a protruding electrode projected upward from the main electrode;

Each of the first-second assembly wiring, the second-second assembly wiring, and the third-second assembly wiring may include a main electrode; and a plurality of bridge electrodes branching from the main electrode; and the protruding electrode and the plurality of bridge electrodes are disposed on a same layer, the protruding electrode of the first-first assembly wiring is disposed in a central region of the first assembly hole, and the plurality of bridge electrodes of the first-second assembly wiring may be disposed radially centered around the protruding electrode.

The first gap region may include a plurality of first gap regions, the protruding electrode of the first-first assembly wiring and the plurality of bridge electrodes of the first-second assembly wiring have the plurality of gap regions, and the first ring electrode of the first semiconductor light emitting device may be positioned in the plurality of first gap regions.

The second gap region may include a plurality of second gap regions, the protruding electrode of the second-first assembly wiring and the plurality of bridge electrodes of the second-second assembly wiring have the plurality of second gap regions, and the second ring electrode of the second semiconductor light emitting device may be positioned in the plurality of second gap regions.

The third gap region may include a plurality of third gap regions, the protruding electrode of the third-first assembly wiring and the plurality of bridge electrodes of the third-second assembly wiring have the plurality of third gap regions, and the edge of the plate electrode of the third semiconductor light emitting device may be positioned in the plurality of third gap regions.

A portion of the plate electrode may vertically overlap each of the plurality of bridge electrodes.

Each of the first-second assembly wiring, the second-second assembly wiring, and the third-second assembly wiring may include a main electrode; and an auxiliary electrode extended from the main electrode; and the protruding electrode and the auxiliary electrode are disposed on the same layer, and the protruding electrode is disposed in a central region of each of the first assembly hole, the second assembly hole, and the third assembly hole, and the auxiliary electrode may surround the protruding electrode.

The auxiliary electrode may include a through hole; and the protruding electrode may be disposed in the through hole.

The protruding electrode of the first-first assembly wiring and the auxiliary electrode of the first-second assembly wiring have the first gap region, and the first ring electrode of the first semiconductor light emitting device may be positioned in the first gap region.

The protruding electrode of the second-first assembly wiring and the auxiliary electrode of the second-second assembly wiring have the second gap region, and the second ring electrode of the second semiconductor light emitting device may be positioned in the second gap region.

The protruding electrode of the third-first assembly wiring and the auxiliary electrode of the third-second assembly wiring have the third gap region, and the edge of the plate electrode of the third semiconductor light emitting device may be positioned in the third gap region.

The inner diameter of the first ring electrode may be larger than the diameter of the protruding electrode of the first-first assembly wiring, and the inner diameter of the second ring electrode may be larger than the diameter of the protruding electrode of the second-first assembly wiring.

The diameter of the plate electrode may be larger than the diameter of the protruding electrode of the third-first assembly wiring.

The display device may include a connecting electrode surrounding the first semiconductor light emitting device, the second semiconductor light emitting device, and the third semiconductor light emitting device in each of the first assembly hole, the second assembly hole, and the third assembly hole; and an electrode wiring on an upper side of each of the first semiconductor light emitting device, the second semiconductor light emitting device and the third semiconductor light emitting device; and the connection electrode may be connected to at least one assembly wiring among each of the pair of first assembly wirings, the pair of second assembly wirings and the pair of third assembly wirings.

### Advantageous Effects

As shown in FIGS. 8 and 9, a plurality of gap regions (G1, G2, G3) that form the largest DEP force at the edges of the first assembly hole (340H1), the second assembly hole (340H2) and the third assembly hole (340H3) arranged in each of the first sub-pixel (PX1), the second sub-pixel (PX2) and the third sub-pixel (PX3) constituting the unit pixel (PX) may be positioned. That is, a plurality of first gap regions (G1) may be positioned at the edges of the first assembly hole (340H1) of the first sub-pixel (PX1). A plurality of second gap regions (G2) may be positioned at the edge of the second assembly hole (340H2) of the second sub-pixel (PX2). A third gap region (G3) may be positioned at the edge of the third assembly hole (340H3) of the third sub-pixel (PX3). The DEP force may be formed to the greatest extent in each of these gap regions (G1, G2, G3).

In this case, a first ring electrode (154-1) of the first semiconductor light emitting device (150-1), a second ring electrode (154-2) of the second semiconductor light emitting device (150-2), and a plate electrode (154-3) of the third semiconductor light emitting device (150-3) may be designed to correspond to the gap regions (G1, G2, G3) where the DEP force may be formed to the greatest extent. That is, the first ring electrode (154-1) may be formed at a lower edge of the first semiconductor light emitting device (150-1), the second ring electrode (154-2) may be formed at a lower edge of the second semiconductor light emitting device (150-2), and the plate electrode (1543) may be formed at a lower edge of the third semiconductor light emitting device (150-3).

Therefore, during self-assembly, the largest DEP force may be formed in each of the multiple gap regions (G1, G2, G3) located at the edges of each of the first assembly hole (340H1), the second assembly hole (340H2), and the third assembly hole (340H3). The first ring electrode (154-1) of the first semiconductor light emitting device (150-1), the second ring electrode (154-2) of the second semiconductor light emitting device (150-2), and the plate electrode (154-3) of the third semiconductor light emitting device (150-3) may be strongly pulled by the largest DEP force formed in each of the plurality of gap regions (G1, G2, G3), so that the first semiconductor light emitting device (150-1), the second semiconductor light emitting device (150-2), and the third semiconductor light emitting device (150-3) may be quickly assembled into the first assembly hole (340H1), the second assembly hole (340H2), and the third assembly hole (340H3), respectively.

In addition, the lower edges of the first semiconductor light emitting device (150-1), the second semiconductor light emitting device (150-2), and the third semiconductor light emitting device (150-3) may be evenly and strongly pulled by the largest DEP force formed in each of the multiple gap regions (G1, G2, G3) at the edges of the first assembly hole (340H1), the second assembly hole (340H2), and the third assembly hole (340H3), so that the first semiconductor light emitting device (150-1), the second semiconductor light emitting device (150-2), and the third semiconductor light emitting device (150-3) may be stably placed in the assembly holes without shaking.

Meanwhile, as an example, as illustrated in FIGS. 8 and 9, gap regions (G1, G2, G3) may be regions formed by the distance between protruding electrodes (31-3, 323-3, 325-3) of the first assembly wiring (321, 323, 325) and multiple bridge electrodes (322-2a to 322-2d, 324-2a to 324-2d, 326-2a to 326-2d) of the second assembly wiring (322, 324, 326). Since the area excluding the plurality of bridge electrodes (322-2a to 322-2d, 324-2a to 324-2d, 326-2a to 326-2d) in each sub-pixel (PX1, PX2, PX3) becomes a through hole (H11, H21, H31), the area where the first assembly wiring (321, 323, 325) and the second assembly wiring (322, 324, 326) vertically overlap may be reduced, so that the capacity of the parasitic capacitance may be reduced. By reducing the capacity of the parasitic capacitance, the loss of the AC voltage between the first assembly wiring (321, 323, 325) and the second assembly wiring (322, 324, 326) caused by the parasitic capacitance may be reduced. Accordingly, a sufficiently large DEP force may be formed even with a smaller AC voltage, so that power consumption may be reduced.

As another example, as illustrated in FIG. 21, gap regions (G1, G2, G3) may be regions formed by the distance between the protruding electrode (31-3, 323-3, 325-3) of the first assembly wiring (321, 323, 325) and the auxiliary electrode (322-4, 324-4, 326-4) of the second assembly wiring (322, 324, 326). Since the auxiliary electrode (322-4, 324-4, 326-4) of the second assembly wiring (322, 324, 326) is disposed along the perimeter of the protruding electrode (31-3, 323-3, 325-3) of the first assembly wiring (321, 323, 325), the gap regions (G1, G2, G3) may be positioned along the perimeter of the protruding electrode (31-3, 323-3, 325-3) of the first assembly wiring (321, 323, 325). Accordingly, the gap area (G1, G2, G3) forms the DEP force the largest along the perimeter of the protruding electrode (31-3, 323-3, 325-3) of the first assembly wiring (321, 323, 325), so that a uniform DEP force is applied along the lower edge of the semiconductor light emitting device (150-1, 150-2, 150-3). Therefore, the semiconductor light emitting device (150-1, 150-2, 150-3) may be stably assembled into the assembly hole (340H1, 340H2, 340H3) without shaking.

Meanwhile, the assembly holes (340H1, 340H2, 340H3) of each of the plurality of sub-pixels (PX1, PX2, PX3) have different sizes, a gap region (G1, G2, G3) may be positioned at the edge of each of the assembly holes (340H1, 340H2, 340H3), and the lower electrodes of each of the semiconductor light emitting devices (150-1, 150-2, 150-3), that is, the first ring electrode (154-1), the second ring electrode (154-2), and the plate electrode (154-3) may be designed to correspond to the gap regions (G1, G2, G3). Accordingly, the semiconductor light emitting devices (150-1, 150-2, 150-3) can be assembled into the predetermined assembly holes (340H1, 340H2, 340H3). That is, as illustrated in FIGS. 19 and 20, when a small-sized third semiconductor light emitting device (150-3) is assembled into the first assembly hole (340H1), the plate electrode (154-3) of the third semiconductor light emitting device (150-3) is not positioned in the gap area (G1) on the edge of the first assembly hole (340H1) or may be positioned at a position far from the gap area (G1), so that the fixing force within the first assembly hole (340H1) is weak and may fall out of the first assembly hole (340H1) due to the attractive force with the magnet (340H1). Accordingly, even if the semiconductor light emitting device (150-1, 150-2, 150-3) is assembled into an assembly hole (340H1, 340H2, 340H3) that is not designated, it may immediately fall out of the assembly hole (340H1, 340H2, 340H3), thereby preventing color mixing defects or assembly defects.

Meanwhile, after the semiconductor light emitting device (150-1, 150-2, 150-3) is assembled into the pre-designated assembly hole (340H1, 340H2, 340H3), the semiconductor light emitting device (150-1, 150-2, 150-3) may be strongly fixed by the largest DEP force formed at the edge of each of the assembly holes (340H1, 340H2, 340H3), so that the semiconductor light emitting device (150-1, 150-2, 150-3) may not fall out of the assembly hole (340H1, 340H2, 340H3), thereby further reducing assembly defects.

Additional scope of applicability of the embodiment will become apparent from the detailed description below. However, since various changes and modifications within the spirit and scope of the embodiment may be clearly understood by those skilled in the art, it should be understood that the specific embodiments, such as the detailed description and the preferred embodiments, are given only as examples.

### DESCRIPTION OF DRAWINGS

FIG. 1 illustrates a situation in which color mixing defects occur in a non-published internal technology.

FIG. 2 illustrates a living room of a house in which a display device according to an embodiment is disposed.

FIG. 3 is a block diagram schematically showing a display device according to an embodiment.

FIG. 4 is a circuit diagram showing an example of a pixel of FIG. 3.

FIG. 5 is an enlarged view of the first panel area of the display device of FIG. 2.

FIG. 6 is an enlarged view of the A2 area of FIG. 5.

FIG. 7 is a drawing showing an example of a light emitting device according to an embodiment being assembled on a substrate by a self-assembly method.

FIG. 8 is a plan view showing a display device according to the first embodiment.

FIG. 9 is a cross-sectional view taken along the C1-C2 line of FIG. 8.

FIG. 10 illustrates a first semiconductor light emitting device.

FIG. 11 illustrates a second semiconductor light emitting device.

FIG. 12 illustrates a third semiconductor light emitting device.

FIG. 13 illustrates the size relationship between the first semiconductor light emitting device, the second semiconductor light emitting device, and the third semiconductor light emitting device.

FIG. 14 illustrates a portion of the first sub-pixel of FIG. 8.

FIG. 15 illustrates a portion of the second sub-pixel of FIG. 8.

FIG. 16 illustrates a portion of the third sub-pixel of FIG. 8.

FIG. 17 illustrates a first semiconductor light emitting device normally assembled in the first sub-pixel of FIG. 8.

FIG. 18 is a first example of a color mixing defect that occurred in the first sub-pixel of FIG. 8.

FIG. 19 is a second example of a color mixing defect that occurred in the first sub-pixel of FIG. 8.

FIG. 20 is a third example of a color mixing defect that occurred in the first sub-pixel of FIG. 8.

FIG. 21 illustrates a display device according to the second embodiment.

The sizes, shapes, and values of the components illustrated in the drawings may differ from the actual ones. In addition, even if the same components are illustrated with different sizes, shapes, and values between the drawings, this is only an example in the drawings, and the same components may have the same sizes, shapes, and values between the drawings.

### MODE FOR INVENTION

Hereinafter, the embodiments disclosed in this specification will be described in detail with reference to the attached drawings, and regardless of the drawing symbols, the same or similar components will be given the same reference numbers and any redundant description thereof will be omitted. The suffixes ‘module’ and ‘part’ used for components in the following description are given or used interchangeably in consideration of the ease of writing the specification, and do not have distinct meanings or roles in themselves. In addition, the attached drawings are intended to facilitate easy understanding of the embodiments disclosed in this specification, and the technical ideas disclosed in this specification are not limited by the attached drawings. In addition, when an element such as a layer, region, or substrate is referred to as existing ‘on’ another element, this may include that it may be directly on the other element or that other intermediate elements may exist between them.

The display device described in this specification may include a TV, a signage, a mobile phone, a smart phone, a HUD (head-up display) for a car, a backlight unit for a laptop computer, a display for VR or AR, etc. However, the configuration according to the embodiments described in this specification may be applied to a device capable of displaying, even if it is a new product type developed in the future.

The following describes a light emitting device according to an embodiment and a display device including the same.

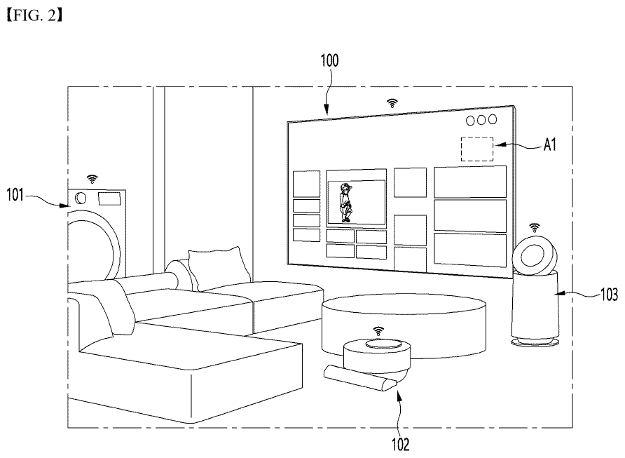

FIG. 2 illustrates a living room of a house in which a display device according to an embodiment is disposed.

Referring to FIG. 2, the display device (100) of the embodiment can display the status of various electronic products such as a washing machine (101), a robot vacuum cleaner (102), and an air purifier (103), communicate with each electronic product based on IoT, and control each electronic product based on the user's setting data.

The display device (100) according to the embodiment can include a flexible display manufactured on a thin and flexible substrate. The flexible display may be bent or rolled like paper while maintaining the characteristics of a conventional flat panel display.

In the flexible display, visual information may be implemented by independently controlling the light emission of unit pixels arranged in a matrix form. A unit pixel means the minimum unit for implementing one color. The unit pixel of the flexible display may be implemented by a light emitting element. In the embodiment, the light emitting element may be a Micro-LED or a Nano-LED, but is not limited thereto.

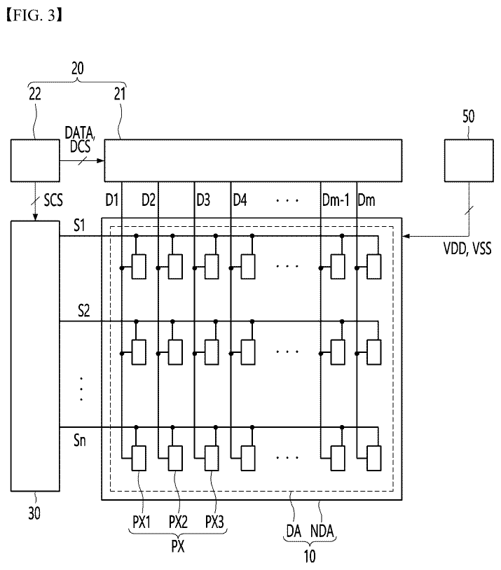

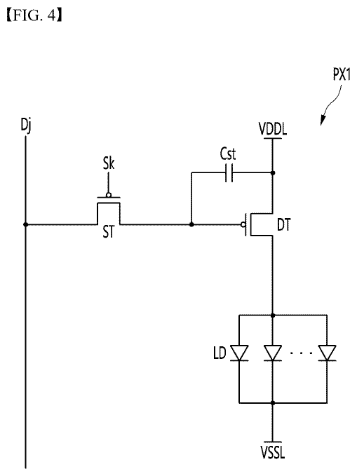

FIG. 3 is a block diagram schematically showing a display device according to an embodiment, and FIG. 4 is a circuit diagram showing an example of a pixel of FIG. 3.

Referring to FIG. 3 and FIG. 4, the display device according to the embodiment may include a display panel (10), a driving circuit (20), a scan driving unit (30), and a power supply circuit (50).

The display device (100) of the embodiment may drive a light emitting device in an active matrix (AM) method or a passive matrix (PM) method.

The driving circuit (20) may include a data driving unit (21) and a timing control unit (22).

The display panel (10) may be formed in a rectangular shape, but is not limited thereto. That is, the display panel (10) may be formed in a circular or oval shape. At least one side of the display panel (10) may be formed to be bent at a predetermined curvature.

The display panel (10) may be divided into a display area (DA) and a non-display area (NDA) arranged around the display area (DA). The display area (DA) is an area where pixels (PX) are formed to display an image. The display panel (10) can include data lines (D1 to Dm, m is an integer larger than or equal to 2), scan lines (S1 to Sn, n is an integer larger than or equal to 2) intersecting the data lines (D1 to Dm), a high-potential voltage line (VDDL) to which a high-potential voltage is supplied, a low-potential voltage line (VSSL) to which a low-potential voltage is supplied, and pixels (PX) connected to the data lines (D1 to Dm) and the scan lines (S1 to Sn).

Each of the pixels (PX) can include a first sub-pixel (PX1), a second sub-pixel (PX2), and a third sub-pixel (PX3). The first sub-pixel (PX1) can emit first color light of the first dominant wavelength, the second sub-pixel (PX2) can emit second color light of the second dominant wavelength, and the third sub-pixel (PX3) can emit third color light of the third dominant wavelength. The first color light may be red light, the second color light may be green light, and the third color light may be blue light, but is not limited thereto. In addition, although FIG. 3 exemplifies that each of the pixels (PX) may include three sub-pixels, it is not limited thereto. That is, each of the pixels (PX) can include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line (VDDL). The first sub-pixel (PX1) may include light emitting devices (LD) as shown in FIG. 4, a plurality of transistors for supplying current to the light emitting devices (LD), and at least one capacitor (Cst).

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light-emitting diode including a first electrode, a plurality of conductivity type semiconductor layers, and a second electrode. Here, the first electrode may be an anode electrode, and the second electrode may be a cathode electrode, but this is not limited thereto.

The light emitting device (LD) may be one of a horizontal light emitting device, a flip-chip light emitting device, and a vertical light emitting device.

The plurality of transistors may include a driving transistor (DT) that supplies current to the light emitting devices (LD) as shown in FIG. 4, and a scan transistor (ST) that supplies a data voltage to the gate electrode of the driving transistor (DT). The driving transistor (DT) may include a gate electrode connected to the source electrode of the scan transistor (ST), a source electrode connected to a high-potential voltage line (VDDL) to which a high-potential voltage is applied, and a drain electrode connected to the first electrodes of the light emitting devices (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

A capacitor (Cst) may be formed between the gate electrode and the source electrode of the driving transistor (DT). The storage capacitor (Cst) charges the difference between the gate voltage and the source voltage of the driving transistor (DT).

The driving transistor (DT) and the scan transistor (ST) may be formed as thin film transistors. In addition, in FIG. 4, the driving transistor (DT) and the scan transistor (ST) are described mainly as being formed as P-type MOSFETs (Metal Oxide Semiconductor Field Effect Transistors), but the present invention is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, in FIG. 4, the first sub-pixel (PX1), the second sub-pixel (PX2), and the third sub-pixel (PX3) each includes a 2T1C (2 Transistor-1 capacitor) having one driving transistor (DT), one scan transistor (ST), and one capacitor (Cst), but the present invention is not limited thereto. The first sub-pixel (PX1), the second sub-pixel (PX2), and the third sub-pixel (PX3) each may include a plurality of scan transistors (ST) and a plurality of capacitors (Cst).

The second sub-pixel (PX2) and the third sub-pixel (PX3) may be expressed in substantially the same circuit diagram as the first sub-pixel (PX1), so a detailed description thereof will be omitted.

The driving circuit (20) outputs signals and voltages for driving the display panel (10). To this end, the driving circuit (20) may include a data driving unit (21) and a timing control unit (22).

The data driving unit (21) receives digital video data (DATA) and a source control signal (DCS) from the timing control unit (22). The data driving unit (21) converts digital video data (DATA) into analog data voltages according to the source control signal (DCS) and supplies the data lines (D1 to Dm) of the display panel (10).

The timing control unit (22) receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system-on-chip of a TV, etc.

The timing control unit (22) generates control signals for controlling the operation timing of the data driving unit (21) and the scan driving unit (30). The control signals may include a source control signal (DCS) for controlling the operation timing of the data driving unit (21) and a scan control signal (SCS) for controlling the operation timing of the scan driving unit (30).

The driving circuit (20) may be placed in a non-display area (NDA) provided on one side of the display panel (10). The driving circuit (20) may be formed as an integrated circuit (IC) and mounted on the display panel (10) using a COG (chip on glass) method, a COP (chip on plastic) method, or an ultrasonic bonding method, but the present invention is not limited thereto. For example, the driving circuit (20) may be mounted on a circuit board (not shown) rather than on the display panel (10).

The data driving unit (21) may be mounted on the display panel (10) using a COG (chip on glass) method, a COP (chip on plastic) method, or an ultrasonic bonding method, and the timing control unit (22) may be mounted on a circuit board.

The scan driving unit (30) receives a scan control signal (SCS) from the timing control unit (22). The scan driving unit (30) generates scan signals according to the scan control signal (SCS) and supplies them to the scan lines (S1 to Sn) of the display panel (10). The scan driving unit (30) may include a plurality of transistors and may be formed in a non-display area (NDA) of the display panel (10). Alternatively, the scan driving unit (30) may be formed as an integrated circuit, in which case it may be mounted on a gate flexible film attached to the other side of the display panel (10).

The circuit board may be attached to pads provided on one edge of the display panel (10) using an anisotropic conductive film. As a result, lead lines of the circuit board may be electrically connected to the pads. The circuit board may be a flexible film such as a flexible printed circuit board, a printed circuit board, or a chip on film. The circuit board may be bent to the bottom of the display panel (10). As a result, one side of the circuit board may be attached to one edge of the display panel (10), and the other side may be connected to a system board on which a host system is mounted, and may be disposed on the bottom of the display panel (10).

The power supply circuit (50) may generate voltages required for driving the display panel (10) from the main power applied from the system board and supply the voltages to the display panel (10). For example, the power supply circuit (50) can generate a high-potential voltage (VDD) and a low-potential voltage (VSS) for driving the light emitting devices (LD) of the display panel (10) from the main power supply and supply them to the high-potential voltage line (VDDL) and the low-potential voltage line (VSSL) of the display panel (10). In addition, the power supply circuit (50) can generate and supply driving voltages for driving the driving circuit (20) and the scan driving unit (30) from the main power supply.

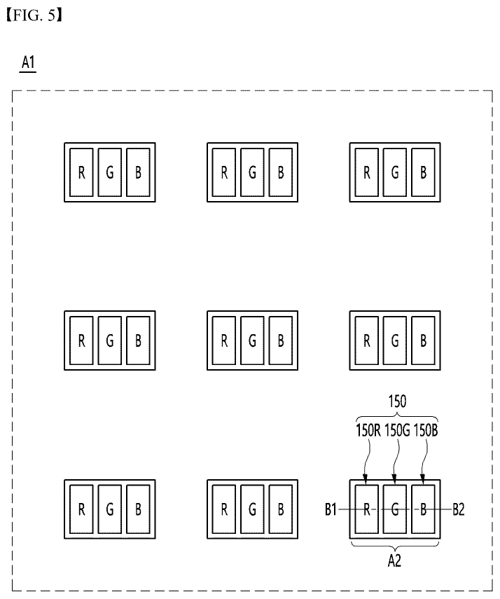

FIG. 5 is an enlarged view of the first panel area in the display device of FIG. 3.

Referring to FIG. 5, the display device (100) of the embodiment may be manufactured by mechanically and electrically connecting a plurality of panel areas such as the first panel area (A1) by tiling.

The first panel area (A1) can include a plurality of semiconductor light emitting devices (150) arranged for each unit pixel (PX of FIG. 3).

For example, a unit pixel (PX) may include a first sub-pixel (PX1), a second sub-pixel (PX2), and a third sub-pixel (PX3). For example, a plurality of red semiconductor light emitting devices (150R) may be disposed in the first sub-pixel (PX1), a plurality of green semiconductor light emitting devices (150G) may be disposed in the second sub-pixel (PX2), and a plurality of blue semiconductor light emitting devices (150B) may be disposed in the third sub-pixel (PX3). The unit pixel (PX) may further include a fourth sub-pixel in which no semiconductor light emitting device is disposed, but this is not limited thereto.

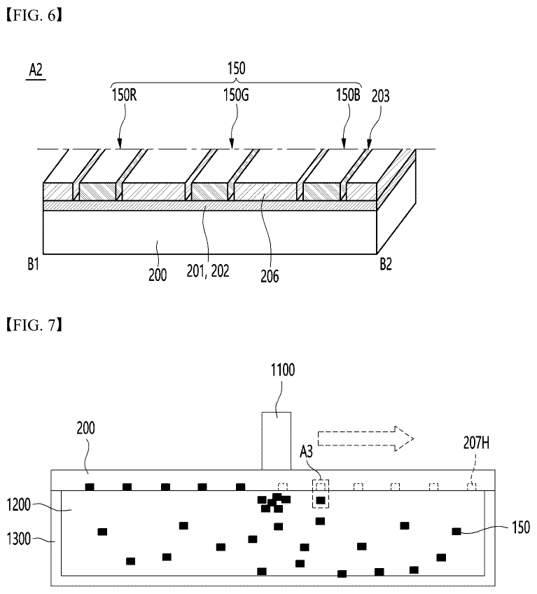

FIG. 6 is an enlarged view of the A2 region of FIG. 5.

Referring to FIG. 6, the display device (100) of the embodiment may include a substrate (200), assembly wiring (201, 202), an insulating layer (206), and a plurality of semiconductor light emitting devices (150). More components may be included.

The assembly wiring may include a first assembly wiring (201) and a second assembly wiring (202) that are spaced apart from each other. The first assembly wiring (201) and the second assembly wiring (202) may be provided to generate a DEP force for assembling the semiconductor light emitting device (150). For example, the semiconductor light emitting device (150) may be one of a horizontal semiconductor light emitting device, a flip-chip semiconductor light emitting device, and a vertical semiconductor light emitting device.

The semiconductor light emitting device (150) may include, but is not limited to, a red semiconductor light emitting device (150), a green semiconductor light emitting device (150G), and a blue semiconductor light emitting device (150B0) to form a unit pixel (sub-pixel), respectively, and may also implement red and green, respectively, by providing a red phosphor and a green phosphor.

The substrate (200) may be a support member that supports components arranged on the substrate (200) or a protective member that protects the components.

The substrate (200) may be a rigid substrate or a flexible substrate. The substrate (200) may be formed of sapphire, glass, silicon, or polyimide. In addition, the substrate (200) may include a flexible material such as PEN (Polyethylene Naphthalate), PET (Polyethylene Terephthalate), etc. In addition, the substrate (200) may be a transparent material, but is not limited thereto. The substrate (200) may function as a support substrate in a display panel, and may also function as an assembly substrate when self-assembling a light emitting device.

The substrate (200) may be a backplane equipped with circuits, such as transistors (ST, DT), capacitors (Cst), and signal wiring, within the sub-pixels (PX1, PX2, PX3) illustrated in FIGS. 3 and 4, but is not limited thereto.

The insulating layer (206) may include an insulating and flexible organic material, such as polyimide, PAC, PEN, PET, polymer, or an inorganic material, such as silicon oxide (SiO2) or silicon nitride series (SiNx), and may be formed integrally with the substrate (200) to form a single substrate.

The insulating layer (206) may be a conductive adhesive layer having adhesiveness and conductivity, and the conductive adhesive layer may have flexibility to enable a flexible function of the display device. For example, the insulating layer (206) may be a conductive adhesive layer such as an anisotropic conductive film (ACF) or an anisotropic conductive medium, a solution containing conductive particles, etc. The conductive adhesive layer may be a layer that is electrically conductive in a vertical direction relative to the thickness, but electrically insulating in a horizontal direction relative to the thickness.

The insulating layer (206) may include an assembly hole (203) into which a semiconductor light emitting device (150) is inserted. Therefore, during self-assembly, the semiconductor light emitting device (150) may be easily inserted into the assembly hole (203) of the insulating layer (206). The assembly hole (203) may be called an insertion hole, a fixing hole, an alignment hole, etc. The assembly hole (203) may also be called a hole.

The assembly hole (203) may be called a hole, a groove, a recess, a pocket, etc.

The assembly hole (203) may be different depending on the shape of the semiconductor light emitting device (150). For example, the red semiconductor light emitting device, the green semiconductor light emitting device, and the blue semiconductor light emitting device may each have different shapes, and may have an assembly hole (203) having a shape corresponding to each shape of the semiconductor light emitting device. For example, the assembly hole (203) may include a first assembly hole for assembling the red semiconductor light emitting device, a second assembly hole for assembling the green semiconductor light emitting device, and a third assembly hole for assembling the blue semiconductor light emitting device. For example, the red semiconductor light emitting device may have a circular shape, the green semiconductor light emitting device may have a first oval shape having a first short axis and a second long axis, and the blue semiconductor light emitting device may have a second oval shape having a second short axis and a second long axis, but this is not limited thereto. The second major axis of the ellipse of the blue semiconductor light emitting device may be larger than the second major axis of the ellipse of the green semiconductor light emitting device, and the second minor axis of the ellipse of the blue semiconductor light emitting device may be smaller than the first minor axis of the ellipse of the green semiconductor light emitting device.

Meanwhile, the method of mounting the semiconductor light emitting device (150) on the substrate (200) may include, for example, a self-assembly method (FIG. 7) and a transfer method.

FIG. 7 is a drawing showing an example of assembling a light emitting device according to an embodiment on a substrate by a self-assembly method.

Based on FIG. 7, an example of assembling a semiconductor light emitting device according to an embodiment on a display panel by a self-assembly method using an electromagnetic field will be described.

The assembly substrate (200) described below may also function as a panel substrate (200a) in the display device after assembling the light emitting device, but the embodiment is not limited thereto.

Referring to FIG. 7, a semiconductor light emitting device (150) may be introduced into a chamber (1300) filled with a fluid (1200), and the semiconductor light emitting device (150) may be moved to an assembly substrate (200) by a magnetic field generated from an assembly device (1100). At this time, a light emitting element (150) adjacent to an assembly hole (207H) of an assembly substrate (200) can be assembled into the assembly hole (207H) by a DEP force caused by an electric field of assembly wirings. The fluid (1200) may be water such as ultrapure water, but is not limited thereto. The chamber may be called a water tank, a container, a vessel, etc.

After the semiconductor light emitting device (150) is introduced into the chamber (1300), the assembly substrate (200) may be placed on the chamber (1300). According to an embodiment, the assembly substrate (200) may be introduced into the chamber (1300).

The semiconductor light emitting device (150) may be a vertical semiconductor light emitting device or a horizontal light emitting device, but is not limited thereto.

The semiconductor light emitting device (150) may include a magnetic layer (not shown) having a magnetic substance. The magnetic layer may include a metal having magnetism, such as nickel (Ni). Since the semiconductor light emitting device (150) introduced into the fluid may include the magnetic layer, it may move to the assembly substrate (200) by a magnetic field generated from the assembly device (1100). The magnetic layer may be disposed on the upper side or lower side or both sides of the light emitting device.

The semiconductor light emitting device (150) may include a passivation layer (156) surrounding the upper surface and the side surface. The passivation layer (156) may be formed by using an inorganic insulator such as silica or alumina through PECVD, LPCVD, sputtering deposition, etc. In addition, the passivation layer (156) may be formed by using a method of spin coating an organic material such as photoresist or a polymer material.

The semiconductor light emitting device (150) can include a first conductivity type semiconductor layer (152a), a second conductivity type semiconductor layer (152c), and an active layer (152b) disposed therebetween. The first conductivity type semiconductor layer (152a) may be an n-type semiconductor layer, and the second conductivity type semiconductor layer (152c) may be a p-type semiconductor layer, but is not limited thereto. The first conductivity type semiconductor layer (152a), the second conductivity type semiconductor layer (152c), and the active layer (152b) disposed therebetween can form a light-emitting portion (152). The light-emitting portion (152) may be called a light-emitting layer, a light-emitting region, etc.

The first electrode (layer) (154a) may be disposed under the first conductivity type semiconductor layer (152a), and the second electrode (layer) (154b) may be disposed on the second conductivity type semiconductor layer (152c). To this end, a portion of the first conductivity type semiconductor layer (152a) or the second conductivity type semiconductor layer (152c) may be exposed to the outside. Accordingly, after the semiconductor light emitting device (150) is assembled on the assembly substrate (200), a portion of the passivation layer (156) may be etched in the manufacturing process of the display device.

The first electrode (154a) may include at least one layer. For example, the first electrode (154a) may include an ohmic layer, a reflective layer, a magnetic layer, a conductive layer, an anti-oxidation layer, an adhesive layer, etc. The ohmic layer may include Au, AuBe, etc. The reflective layer may include Al, Ag, etc. The magnetic layer may include Ni, Co, etc. The conductive layer may include Cu, etc. The anti-oxidation layer may include Mo, etc. The adhesive layer may include Cr, Ti, etc.

The second electrode (154b) may include a transparent conductive layer. For example, the second electrode (154b) may include ITO, IZO, etc.

The assembly substrate (200) may include a pair of first assembly wiring (201) and second assembly wiring (202) corresponding to each of the semiconductor light emitting devices (150) to be assembled. Each of the first assembly wiring (201) and the second assembly wiring (202) may be formed by laminating a single metal or a metal alloy, a metal oxide, etc. in multiple layers. For example, each of the first assembly wiring (201) and the second assembly wiring (202) may include Cu, Ag, Ni, Cr, Ti, Al, Rh, Pd, Ir, Ru, Mg, Zn, Pt, Au, Hf, etc. but is not limited thereto.

The first assembly wiring (201) and the second assembly wiring (202) form an electric field as an AC voltage is applied, and the semiconductor light emitting device (150) inserted into the assembly hole (207H) may be fixed by the DEP force caused by the electric field. The gap between the first assembly wiring (201) and the second assembly wiring (202) may be smaller than the width of the semiconductor light emitting device (150) and the width of the assembly hole (207H), and the assembly position of the semiconductor light emitting device (150) using the electric field may be fixed more precisely.

An insulating layer (215) may be formed on the first assembly wiring (201) and the second assembly wiring (202) to protect the first assembly wiring (201) and the second assembly wiring (202) from the fluid (1200) and prevent leakage of current flowing in the first assembly wiring (201) and the second assembly wiring (202). For example, the insulating layer (215) may be formed as a single layer or multiple layers of an inorganic insulator such as silica or alumina or an organic insulator. The insulating layer (215) may have a minimum thickness to prevent damage to the first assembly wiring (201) and the second assembly wiring (202) during assembly of the semiconductor light emitting device (150), and may have a maximum thickness to stably assemble the semiconductor light emitting device (150).

A partition wall (207) may be formed on the upper portion of the insulating layer (215). Some areas of the partition wall (207) may be located on the upper side of the first assembly wiring (201) and the second assembly wiring (202), and the remaining areas may be located on the upper side of the assembly board (200).

Meanwhile, when manufacturing the assembly board (200), some of the partition walls formed on the upper side of the insulating layer (215) may be removed, thereby forming an assembly hole (207H) in which each of the semiconductor light emitting devices (150) is coupled and assembled to the assembly board (200).

An assembly hole (207H) in which the semiconductor light emitting devices (150) are coupled may be formed on the assembly board (200), and a surface on which the assembly hole (207H) may be formed may be in contact with a fluid (1200). The assembly hole (207H) may guide the exact assembly position of the semiconductor light emitting device (150).

Meanwhile, the assembly hole (207H) may have a shape and size corresponding to the shape of the semiconductor light emitting device (150) to be assembled at the corresponding position. Accordingly, it is possible to prevent another semiconductor light emitting device from being assembled in the assembly hole (207H) or multiple semiconductor light emitting devices from being assembled.

Referring again to FIG. 7, after the assembly substrate (200) is placed in the chamber, an assembly device (1100) that applies a magnetic field may move along the assembly substrate (200). The assembly device (1100) may be a permanent magnet or an electromagnet.

The assembly device (1100) may move in contact with the assembly substrate (200) in order to maximize the area to which the magnetic field applies within the fluid (1200). Depending on the embodiment, the assembly device (1100) may include multiple magnetic bodies or a magnetic body having a size corresponding to the assembly substrate (200). In this case, the movement distance of the assembly device (1100) may be limited within a predetermined range.

The semiconductor light emitting device (150) in the chamber (1300) may move toward the assembly device (1100) and the assembly substrate (200) by the magnetic field generated by the assembly device (1100).

The semiconductor light emitting device (150) may enter the assembly hole (207H) and be fixed by the DEP force formed by the electric field between the assembly wirings (201, 202) while moving toward the assembly device (1100).

Specifically, the first and second assembly wirings (201, 202) form an electric field by the AC power, and the DEP force may be formed between the assembly wirings (201, 202) by this electric field. By this DEP force, the semiconductor light emitting device (150) may be fixed to the assembly hole (207H) on the assembly board (200).

At this time, a predetermined solder layer (not shown) may be formed between the light emitting device (150) assembled on the assembly hole (207H) of the assembly board (200) and the assembly wiring (201, 202), thereby improving the bonding strength of the light emitting device (150).

In addition, a molding layer (not shown) may be formed on the assembly hole (207H) of the assembly board (200) after assembly. The molding layer may be a transparent resin or a resin containing a reflective material or a scattering material.

By the self-assembly method using the electromagnetic field described above, the time required for each semiconductor light emitting device to be assembled on the board may be drastically shortened, so that a large-area, high-pixel display may be implemented more quickly and economically.

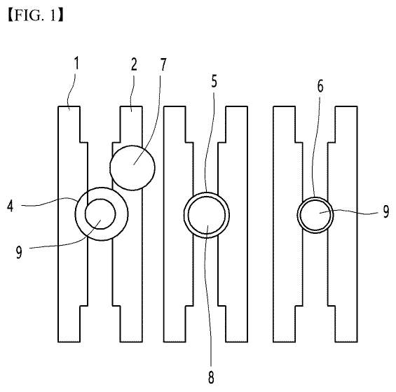

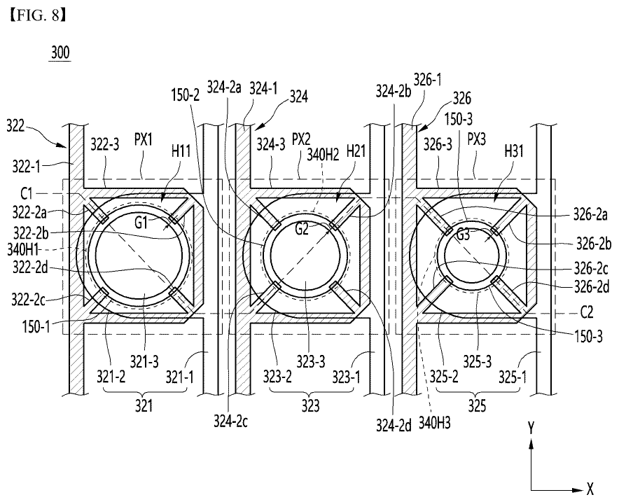

Hereinafter, various embodiments for solving the above-described problem will be described with reference to FIGS. 8 to 21. Any description omitted below may be easily understood from the descriptions described above with respect to FIGS. 1 to 7 and the corresponding drawings.

### First Embodiment

FIG. 8 is a plan view illustrating a display device according to the first embodiment.

Referring to FIG. 8, the display device (300) according to the first embodiment may include a plurality of sub-pixels (PX1, PX2, PX3) constituting a unit pixel. For example, a first light may be output from the first sub-pixel (PX1), a second light may be output from the second sub-pixel (PX2), and a third light may be output from the third sub-pixel (PX3). An image may be displayed by the first light, the second light, and the third light. For example, the first light may be red light, the second light may be green light, and the third light may be blue light, but this is not limited thereto.

The first sub-pixel (PX1) may include a first semiconductor light emitting device (150-1), the second sub-pixel (PX2) may include a second semiconductor light emitting device (150-2), and the third sub-pixel (PX3) may include a third semiconductor light emitting device (150-3). For example, the first semiconductor light emitting device (150-1) may emit the first light, the second semiconductor light emitting device (150-2) may emit the second light, and the third semiconductor light emitting device (150-3) may emit the third light.

The first semiconductor light emitting device (150-1), the second semiconductor light emitting device (150-2), and the third semiconductor light emitting device (150-3) may each have a size of at least a micrometer or less.

In an embodiment, the first semiconductor light emitting device (150-1), the second semiconductor light emitting device (150-2), and the third semiconductor light emitting device (150-3) can be assembled on the substrate (310) using a self-assembly method.

To this end, each of the plurality of sub-pixels (PX1, PX2, PX3) may include a pair of assembly wirings (321 to 326) and assembly holes (340H1, 340H2, 340H3).

Specifically, the first sub-pixel (PX1) may include a pair of first assembly wirings (321, 322) and a first assembly hole (340H1). In the first sub-pixel (PX1), the first assembly hole (340H1) is disposed on a pair of first assembly wirings (321, 322), and the first semiconductor light emitting device (150-1) can be assembled into the first assembly hole (340H1) by the first DEP force formed on the pair of first assembly wirings (321, 322).

The second sub-pixel (PX2) may include a pair of second assembly wirings (323, 324) and a second assembly hole (340H2). In the second sub-pixel (PX2), the second assembly hole (340H2) is disposed on the pair of second assembly wirings (323, 324), and the second semiconductor light emitting device (150-2) can be assembled to the second assembly hole (340H2) by a second DEP force formed on the pair of second assembly wirings (323, 324).

The third sub-pixel (PX3) may include a pair of third assembly wirings (325, 326) and a third assembly hole (340H3). In the third sub-pixel (PX3), the third assembly hole (340H3) is disposed on a pair of third assembly wirings (325, 326), and the third semiconductor light emitting device (150-3) can be assembled to the third assembly hole (340H3) by a third DEP force formed on a pair of third assembly wirings (325, 326).

The first DEP force, the second DEP force, and the third DEP force may be different from each other, but are not limited thereto.

In an embodiment, in order for the first semiconductor light emitting device (150-1), the second semiconductor light emitting device (150-2), and the third semiconductor light emitting device (150-3) to be assembled simultaneously using a self-assembly method, the first assembly hole (340H1), the second assembly hole (340H2), and the third assembly hole (340H3) may have different sizes from each other. Accordingly, the first semiconductor light emitting device (150-1), the second semiconductor light emitting device (150-2), and the third semiconductor light emitting device (150-3) may also have different sizes.

For example, the size of the first assembly hole (340H1) may be larger than the size of the second assembly hole (340H2), and the size of the second assembly hole (340H2) may be larger than the size of the third assembly hole (340H3), but this is not limited. For example, the first semiconductor light emitting device (150-1) may have a size smaller than the size of the first assembly hole (340H1) and larger than the size of the second semiconductor light emitting device (150-2). For example, the second semiconductor light emitting device (150-2) may have a size smaller than the size of the second assembly hole (340H2) and larger than the size of the third semiconductor light emitting device (150-3). For example, the third semiconductor light emitting device (150-3) may have a size smaller than the size of the third assembly hole (340H3).

When the self-assembly process is performed, the size of the first semiconductor light emitting device (150-1) is larger than the size of the second assembly hole (340H2) or the size of the third assembly hole (340H3), so the first semiconductor light emitting device (150-1) can be assembled into the first assembly hole (340H1) without being assembled into the second assembly hole (340H2) or the third assembly hole (340H3). The size of the second semiconductor light emitting device (150-2) is larger than the size of the third assembly hole (340H3), so the second semiconductor light emitting device (150-2) can be assembled into the second assembly hole (340H2) without being assembled into the third assembly hole (340H3). The third semiconductor light emitting device (150-3) can be assembled into the third assembly hole (340H3).

However, since the size of the third semiconductor light emitting device (150-3) is smaller than the size of the first assembly hole (340H1) or the size of the second assembly hole (340H2), a color mixing defect may occur when the third semiconductor light emitting device (150-3) is assembled into the first assembly hole (340H1) or the third assembly hole (340H3). Similarly, since the size of the second semiconductor light emitting device (150-2) is smaller than the size of the first assembly hole (340H1), a color mixing defect may occur when the second semiconductor light emitting device (150-2) is assembled into the first assembly hole (340H1).

The embodiment can prevent the above-described color mixing defect by changing the arrangement shape of a pair of assembly wirings (321 to 326) of each of a plurality of sub-pixels (PX1, PX2, PX3) and changing the shape of the lower electrodes (154-1, 154-2, 154-3) of each of a plurality of semiconductor light emitting devices (150-1, 150-2, 150-3).

The arrangement shape of a pair of assembly wirings (321 to 326) may be changed so that a DEP force may be formed at the edge of the assembly hole (340H1, 340H2, 340H3) of each of a plurality of sub-pixels (PX1, PX2, PX3).

A pair of assembly wirings (321 to 326) may include a pair of first assembly wirings (321, 322), a pair of second assembly wirings (323, 324), and a pair of third assembly wirings (325, 326). A pair of first assembly wirings may include a first-first assembly wiring (321) and a second-first assembly wiring (322). A pair of second assembly wirings may include a first-second assembly wiring (323) and a second-second assembly wiring (324). A pair of third assembly wirings may include a first-third assembly wiring (325) and a second-third assembly wiring (326).

For example, some areas of the first assembly wiring such as the first-first assembly wiring (321), the first-second assembly wiring (323), and the first-third assembly wiring (325), those are the protruding electrodes (321-3, 323-3, 325-3), may be positioned in each center area of the assembly holes (340H1, 340H2, 340H3). And some areas of the second assembly wiring such as the second-first assembly wiring (322), the second-second assembly wiring (324), and the second-third assembly wiring (326), those are a plurality of bridge electrodes (322-2a to 322-2d, 323-2a to 324-2d, 326-2a to 326-2d) may be positioned at each edge of the assembly holes (340H1, 340H2, 340H3).

The shape of the assembly holes (340H1, 340H2, 340H3) may have a shape corresponding to each shape of the semiconductor light emitting devices (150-1, 150-2, 150-3). The protruding electrodes (321-3, 323-3, 325-3) may have shape corresponding to each shape of the assembly hole (340H1, 340H2, 340H3). For example, when the semiconductor light emitting device (150-1, 150-2, 150-3) is circular, the assembly hole (340H1, 340H2, 340H3) and the protruding electrode (321-3, 323-3, 325-3) may also be circular.

The bridge electrodes (322-2a to 322-2d, 323-2a to 324-2d, 326-2a to 326-2d) of the second assembly wiring (322, 324, 326) may be radially arranged around the protruding electrodes (321-3, 323-3, 325-3) of the first assembly wiring (321, 323, 325).

The protruding electrodes (321-3, 323-3, 325-3) of the first assembly wiring (321, 323, 325) and the bridge electrodes (322-2a to 322-2d, 323-2a to 324-2d, 326-2a to 326-2d) of the second assembly wiring (322, 324, 326) may have a predetermined gap area (G1, G2, G3). That is, the bridge electrodes (322-2a to 322-2d, 323-2a to 324-2d, 326-2a to 326-2d) of the second assembly wiring (322, 324, 326) may be radially spaced apart from the protruding electrodes (321-3, 323-3, 325-3) of the first assembly wiring (321, 323, 325) by a predetermined gap area (G1, G2, G3).

In this case, the DEP forcer may be most strongly formed in the gap region (G1, G2, G3) between the protruding electrodes (321-3, 323-3, 325-3) of the first assembly wirings (321, 323, 325) and the bridge electrodes (322-2a to 322-2d, 323-2a to 324-2d, 326-2a to 326-2d) of the second assembly wirings (322, 324, 326). Therefore, when the number of bridge electrodes (322-2a to 322-2d, 323-2a to 324-2d, 326-2a to 326-2d) of the second assembly wirings (322, 324, 326) is increased, the areas where the DEP force is most strongly formed within the assembly holes (340H1, 340H2, 340H3) are also increased, so that more areas of each of the plurality of semiconductor light emitting devices (150-1, 150-2, 150-3) receive the DEP force, and the plurality of semiconductor light emitting devices (150-1, 150-2, 150-3) can be assembled more quickly and stably.

Meanwhile, the electrodes including the metal in each of the semiconductor light emitting devices (150-1, 150-2, 150-3) may be strongly affected by the DEP force. In particular, the lower electrodes (154-1, 154-2, 154-3) provided at the lower portions of each of the semiconductor light emitting devices (150-1, 150-2, 150-3) may be strongly affected by the DEP force.

In the embodiment, the lower electrodes (154-1, 154-2, 154-3) of each of the semiconductor light emitting devices (150-1, 150-2, 150-3) may be changed to be provided at positions where the DEP force is strongly formed. To this end, each of the first semiconductor light emitting device (150-1) and the second semiconductor light emitting device (150-2) may have ring electrodes (154-1, 154-2) as lower electrodes. The third semiconductor light emitting device (150-3) is provided with a plate electrode (154-3) because it is difficult to form a ring electrode due to its small size, but may also be formed as a ring electrode.

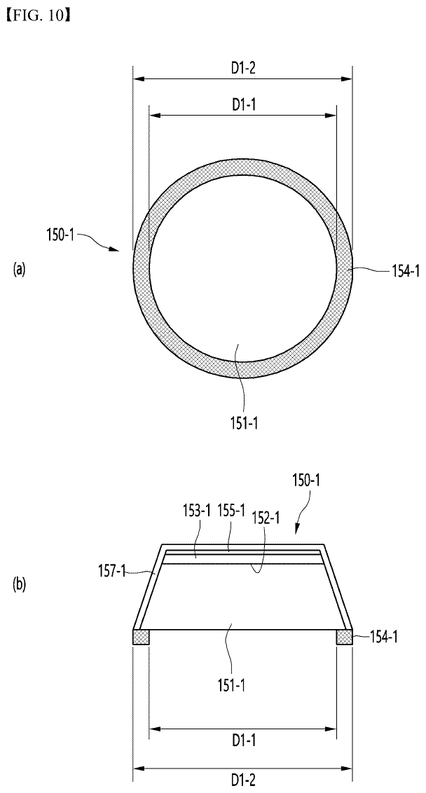

As illustrated in FIG. 10, the first semiconductor light emitting device (150-1) may include a first conductivity type semiconductor layer (151-1), an active layer (152-1), a second conductivity type semiconductor layer (153-1), a first ring electrode (154-1), a second electrode (155-1), and a passivation layer (157-1).

The first ring electrode (154-1) may be disposed below the first conductivity type semiconductor layer (151-1). The first ring electrode (154-1) may be disposed along an edge of the lower surface of the first conductivity type semiconductor layer (151-1). The first ring electrode (154-1) may have a closed loop shape. The outer shape of the first ring electrode (154-1) may correspond to the shape of the first semiconductor light emitting device (150-1), but is not limited thereto.

Since the first conductivity type semiconductor layer (151-1) of the first ring electrode (154-1) is disposed in a part of the first conductivity type semiconductor layer (151-1), the first conductivity type semiconductor layer (151-1) may be exposed through the hollow of the first ring electrode (154-1) when viewed from below.

The outer diameter (D1-2) of the first ring electrode (154-1) may be larger than the diameter of the active layer (152-1) of the first semiconductor light emitting device (150-1), but is not limited thereto.

As illustrated in FIG. 11, the second semiconductor light emitting device (150-2) may include a first conductivity type semiconductor layer (151-2), an active layer (152-2), a second conductivity type semiconductor layer (153-2), a second ring electrode (154-2), a second electrode (155-2), and a passivation layer (157-2).

The second ring electrode (154-2) may be disposed under the first conductivity type semiconductor layer (151-2). The second ring electrode (154-2) may be disposed along the edge of the lower surface of the first conductivity type semiconductor layer (151-2). The second ring electrode (154-2) may have a closed loop shape. The outer shape of the second ring electrode (154-2) may correspond to the shape of the second semiconductor light emitting device (150-2), but is not limited thereto.

Since the second ring electrode (154-2) is disposed in a part of the first conductivity type semiconductor layer (151-2), the first conductivity type semiconductor layer (151-2) may be exposed through the hollow of the second ring electrode (154-2) when viewed from below.

The outer diameter (D2-2) of the second ring electrode (154-2) may be larger than the diameter of the active layer (152-2) of the second semiconductor light emitting device (150-2), but is not limited thereto.

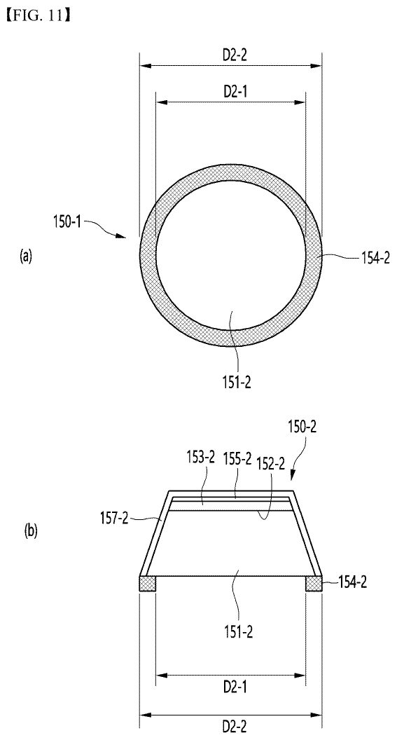

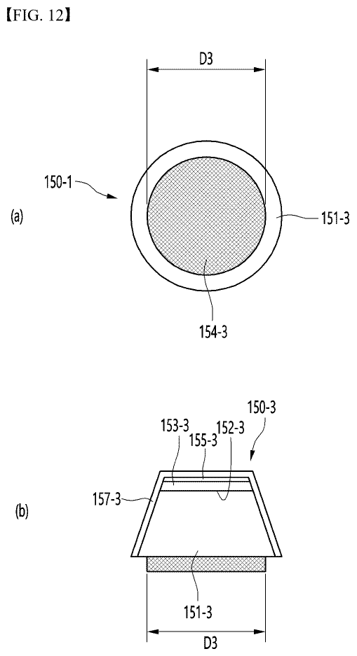

As illustrated in FIG. 12, the third semiconductor light emitting device (150-3) may include a first conductivity type semiconductor layer (151-3), an active layer (152-3), a second conductivity type semiconductor layer (153-3), a plate electrode (154-3), a second electrode (155-3), and a passivation layer (157-3).

The plate electrode (154-3) may be disposed under the first conductivity type semiconductor layer (151-3). The plate electrode (154-3) may be disposed along the edge of the lower surface of the first conductivity type semiconductor layer (151-3). The plate electrode (154-3) may have a closed loop shape. The outer shape of the plate electrode (154-3) may correspond to the shape of the third semiconductor light emitting device (150-3), but is not limited thereto.

The diameter (D3) of the plate electrode (154-3) may be smaller than the diameter of the first conductivity type semiconductor layer (151-3) of the third semiconductor light emitting device (150-3). For example, since the plate electrode (154-3) is disposed in the central region of the first conductivity type semiconductor layer (151-3), the first conductivity type semiconductor layer (151-3) may be exposed through the outer periphery of the plate electrode (154-3) when viewed from below.

The diameter (D3) of the plate electrode (154-3) may be equal to or smaller than the diameter of the active layer (152-3) of the third semiconductor light emitting device (150-3), but is not limited thereto.

The first ring electrode (154-1), the second ring electrode (154-2), and the plate electrode (154-3) may have the same thickness, but is not limited thereto. The first ring electrode (154-1), the second ring electrode (154-2), and the plate electrode (154-3) may be made of the same metal, but is not limited thereto.

FIG. 13 illustrates the size relationship of the first semiconductor light emitting device, the second semiconductor light emitting device, and the third semiconductor light emitting device.

As shown in FIGS. 10 to 13, the outer diameter (D1-2) of the first ring electrode (154-1) may be larger than the outer diameter (D2-2) of the second ring electrode (154-2). The inner diameter (D1-1) of the first ring electrode (154-1) may be larger than the outer diameter (D2-2) of the second ring electrode (154-2).

The diameter (D3) of the plate electrode (154-3) may be smaller than the outer diameter (D2-2) of the second ring electrode (154-2). The diameter (D3) of the plate electrode (154-3) may be smaller than the inner diameter (D2-1) of the second ring electrode (154-2).

As shown in FIG. 13, when the first semiconductor light emitting device (150-1), the second semiconductor light emitting device (150-2) and the third semiconductor light emitting device (150-3) are disposed vertically, the first ring electrode (154-1), the second ring electrode (154-2) and the plate electrode (154-3) may not vertically overlap each other.

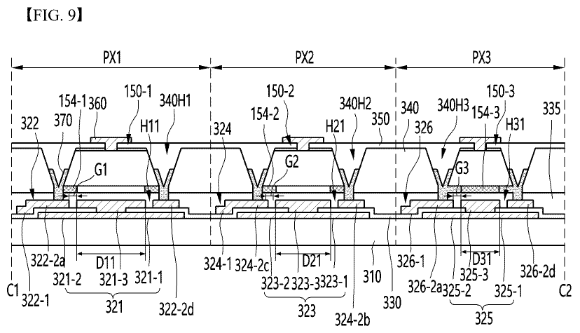

FIG. 9 is a cross-sectional view taken along the C1-C2 line of FIG. 8.

Referring to FIG. 9, the display device (300) according to the first embodiment may include a substrate (310), a first insulating layer (330), a pair of assembly wirings (321 to 326), a second insulating layer (335), a partition wall (340) including a plurality of assembly holes (340H1, 340H2, 340H3), a third insulating layer (350), an electrode wiring (360) and a connecting electrode (370). The display device (300) according to the first embodiment may include a pair of assembly wirings (321 to 326) and a plurality of signal lines connected to electrode wirings (360), although not shown.

A plurality of sub-pixels (PX1, PX2, PX3) may be defined on a substrate (310). The plurality of sub-pixels (PX1, PX2, PX3) may constitute a unit pixel.

A pair of assembly wirings (321 to 326) may include a pair of first assembly wirings (321, 322), a pair of second assembly wirings (323, 324), and a pair of third assembly wirings (325, 326).

Among a pair of assembly wirings (321 to 326), the first assembly wirings (321, 323, 325) may be placed on a substrate (310), and among a pair of assembly wirings (321 to 326), the second assembly wirings (322, 324, 326) may be placed on a first insulating layer (330). A portion of the first assembly wirings (321, 323, 325), that is, protruding regions (321-3, 322-3, 323-3), may be placed on the first insulating layer (330). That is, the protruding regions (321-3, 322-3, 323-3) and the second assembly wirings (322, 324, 326) may be placed on the same layer, that is, the first insulating layer (330).

The first insulation layer (330) can electrically insulate the first assembly wirings (321, 323, 325) and the second assembly wirings (322, 324, 326). To this end, the first insulation layer (330) may be made of a material having excellent insulation properties. For example, the first insulation layer (330) may be made of an inorganic insulation material such as SiNx or SiOx, but is not limited thereto.

As illustrated in FIGS. 8 and 9, the first assembly wirings (321, 323, 325) and the second assembly wirings (322, 324, 326) may be disposed in each of a plurality of sub-pixels (PX1, PX2, PX3).

### The First Sub-Pixel (PX1)

In the first sub-pixel (PX1), a pair of first assembly wirings, that is, the first-first assembly wiring (321) and the second-first assembly wiring (322), may be disposed on the substrate (310).

The assembly wiring (321) may include a main electrode (321-1), a connection electrode (321-2), and a protruding electrode (321-3). The main electrode (321-1) may be disposed to be long along the second direction (Y). The main electrode (321-1) may be disposed to pass through a plurality of first sub-pixels (PX1) positioned along the second direction (Y). The connection electrode (321-2) may be disposed to extend from the main electrode (321-1) and be disposed in the first sub-pixel (PX1). The connection electrode (321-2) may be formed integrally with the main electrode (321-1), but is not limited thereto. The main electrode (321-1) and the connection electrode (321-2) may be formed simultaneously using the same patterning process, but is not limited thereto.

As shown in FIG. 8, the end of the connection electrode (321-2) may have a round shape in the first sub-pixel (PX1), but is not limited thereto.

The protruding electrode (321-3) may be disposed in the center area of the first assembly hole (340H1). The protruding electrode (321-3) may be disposed on the first insulating layer (330). The protruding electrode (321-3) may penetrate the first insulating layer (330) and be connected to the connection electrode (321-2). The protruding electrode (321-3) may be vertically overlapped with the connecting electrode (321-2). The protruding electrode (321-3) may be made of different metal from the main electrode (321-1) or the connecting electrode (321-2), but is not limited thereto. The protruding electrode (321-3) may be individually formed using a separate patterning process from the main electrode (321-1) or the connecting electrode (321-2), but is not limited thereto.

Meanwhile, the second-first assembly wiring (322) may include the main electrode (322-1), the connecting electrode (322-3), and a plurality of bridge electrodes (322-2a to 322-2d).

The main electrode (322-1) may be disposed lengthwise along the second direction (Y). The main electrode (322-1) may be disposed parallel to the main electrode (321-1) of the first-first assembly wiring (321) along the second direction (Y). The main electrode (322-1) may be disposed to pass through a plurality of first sub-pixels (PX1) positioned along the second direction (Y).

The connection electrode (322-3) may be extended from the main electrode (322-1) and arranged in the first sub-pixel (PX1). The connection electrode (322-3) may be formed integrally with the main electrode (322-1), but is not limited thereto. The main electrode (322-1) and the connection electrode (322-3) may be formed simultaneously using the same patterning process, but is not limited thereto. The connection electrode (322-3) may be extended from the main electrode (322-1) and may have a closed loop shape in the first sub-pixel (PX1). For example, one side of the connection electrode (322-3) extends from the first region of the main electrode (322-1), the other side of the connection electrode (322-3) extends from the second region of the main electrode (322-1), and one side of the connection electrode (322-3) and the other side of the connection electrode (322-3) are disposed along the perimeter of the first assembly hole (340H1) in the first sub-pixel (PX1) and can meet each other.

The plurality of bridge electrodes (322-2a to 322-2d) may be branched from the main electrode (322-1). The plurality of bridge electrodes (322-2a to 322-2d) may be branched from the connection electrode (322-3). The plurality of bridge electrodes (322-2a to 322-2d) may be extended from the connection electrode (322-3) toward the center of the first assembly hole (340H1). For example, when four bridge electrodes (322-2a to 322-2d) are provided, the four bridge electrodes (322-2a to 322-2d) may be disposed in directions of 45°, 135°, 225°, and 315° from the center of the first assembly hole (340H1), respectively, but this is not limited thereto. In this case, two bridge electrodes (322-2a, 322-2c) may be simultaneously connected to the main electrode (322-1) and the connection electrode (322-3), respectively, and two bridge electrodes (322-2b, 322-2d) may be connected to the connection electrode (322-3), respectively.

A through hole (H11) may be formed on the inner side of the connection electrode (322-3). In this case, the protruding electrode (321-3) of the first-first assembly wiring (321) may be positioned in the through hole (H11) of the connecting electrode (322-3). The protruding electrode (321-3) of the first-first assembly wiring (321) may be surrounded by the connecting electrode (322-3) or a plurality of bridge electrodes (322-2a to 322-2d). The protruding electrode (321-3) of the first-first assembly wiring (321) may be positioned in the through hole (H11) so as to be spaced apart from the plurality of bridge electrodes (322-2a to 322-2d). In this case, the plurality of bridge electrodes (322-2a to 322-2d) may be spaced apart from the protruding electrode (321-3) of the first-first assembly wiring (321) by a predetermined gap area (G1), respectively.

Some areas of the plurality of bridge electrodes (322-2a to 322-2d) may vertically overlap with the first assembly hole (340H1). That is, some areas of each of the plurality of bridge electrodes (322-2a to 322-2d) may vertically overlap with the first assembly hole (340H1), and other areas of each of the plurality of bridge electrodes (322-2a to 322-2d) may be disposed outside the first assembly hole (340H1).

The main electrode (322-1), the connection electrode (322-3), and the plurality of bridge electrodes (322-2a to 322-2d) may be formed integrally, but this is not limited. The main electrode (322-1), the connection electrode (322-3), and the plurality of bridge electrodes (322-2a to 322-2d) may be formed simultaneously using the same patterning process, but this is not limited.

The main electrode (322-1), the connection electrode (322-3), and the plurality of bridge electrodes (322-2a to 322-2d) may be disposed on the first insulating layer (330). The protruding electrode (321-3) of the first-first assembly wiring (321) may be disposed on the first insulating layer (330). Accordingly, the main electrode (322-1), the connection electrode (322-3), the plurality of bridge electrodes (322-2a to 322-2d) and the protruding electrode (321-3) of the first-first assembly wiring (321) may be disposed on the same layer.

As described above, the protruding electrode (321-3) of the first-first assembly wiring (321) may be positioned in the center area of the first assembly hole (340H1) and may be circular. In this case, the plurality of bridge electrodes (322-2a to 322-2d) may be horizontally spaced apart from the protruding electrode (321-3) of the first-first assembly wiring (321), respectively. For example, the plurality of bridge electrodes (322-2a to 322-2d) may be spaced apart from the protruding electrode (321-3) of the first-first assembly wiring (321) by a predetermined gap area (G1). The predetermined gap area (G1) may be formed at a position corresponding to the edge of the first assembly hole (340H1).

When the first semiconductor light emitting device (150-1) illustrated in FIG. 10 is placed in the first assembly hole (340H1), the first ring electrode (154-1) of the first semiconductor light emitting device (150-1) may be positioned in the gap area (G1) between the protruding electrode (321-3) of the first-first assembly wiring (321) and the plurality of bridge electrodes (322-2a to 322-2d) of the second-first assembly wiring (322). That is, the first ring electrode (154-1) of the first semiconductor light emitting device (150-1) may be vertically overlapped with the corresponding gap region (G1).

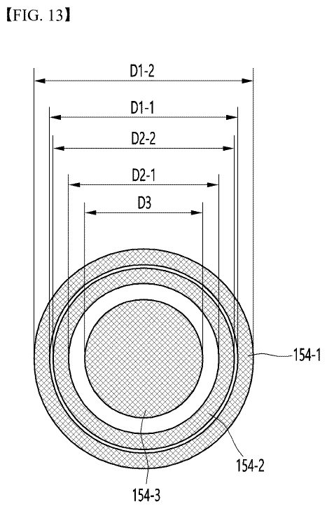

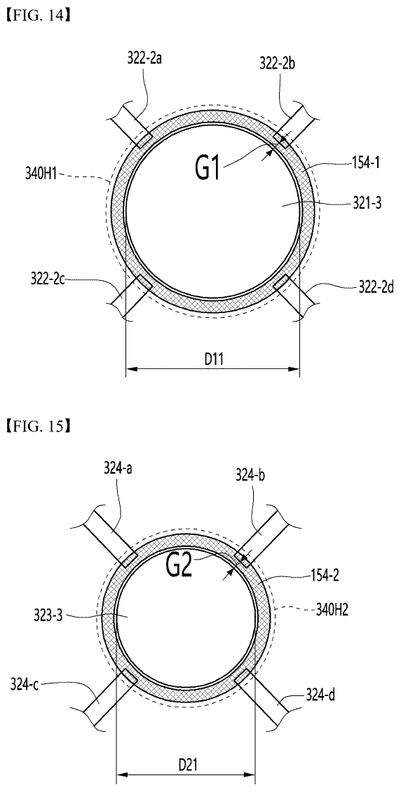

As illustrated in FIG. 14, a portion of each of the plurality of bridge electrodes (322-2a to 322-2d) of the second-first assembly wiring (322) may be positioned within the first assembly hole (340H1). That is, a portion of each of the plurality of bridge electrodes (322-2a to 322-2d) may be vertically overlapped with the first assembly hole (340H1). The protruding electrode (321-3) of the first-first assembly wiring (321) may be positioned in the center region of the first assembly hole (340H1). The plurality of bridge electrodes (322-2a to 322-2d) may be radially arranged with the first assembly hole (340H1) as the center. The plurality of bridge electrodes (322-2a to 322-2d) may be radially arranged around the protruding electrode (321-3) of the first-first assembly wiring (321). In this case, the plurality of bridge electrodes (322-2a to 322-2d) of the second-first assembly wiring (322) may be spaced apart from the protruding electrode (321-3) of the first-first assembly wiring (321) by a predetermined gap area (G1).

When the first semiconductor light emitting device (150-1) is assembled into the first assembly hole (340H1), the first ring electrode (154-1) of the first semiconductor light emitting device (150-1) may be positioned at the edge of the first assembly hole (340H1). The first ring electrode (154-1) of the first semiconductor light emitting device (150-1) may be positioned in a gap region (G1) between the protruding electrode (321-3) of the first-first assembly wiring (321) and the plurality of bridge electrodes (322-2a to 322-2d) of the second-first assembly wiring (322).

The inner diameter (D1-1) of the first ring electrode (154-1) of the first semiconductor light emitting device (150-1) may be larger than the diameter (D11) of the protruding electrode (321-3) of the first-first assembly wiring (321).

Although not illustrated, a portion of the first ring electrode (154-1) of the first semiconductor light emitting device (150-1) may vertically overlap with the protruding electrode (321-3) of the first-first assembly wiring (321), but this is not limited thereto.

Meanwhile, when an AC voltage is applied to the first-first assembly wiring (321) and the second-first assembly wiring (322), the DEP force may be formed to the greatest extent in the gap region (G1) between the protruding electrode (321-3) of the first-first assembly wiring (321) and the multiple bridge electrodes (322-2a to 322-2d) of the second-first assembly wiring (322). Among the regions where a DEP force may be formed by an AC voltage applied to the protruding electrode (321-3) of the first-first assembly wiring (321) and the plurality of bridge electrodes (322-2a to 322-2d) of the second-first assembly wiring (322), the region between the protruding electrode (321-3) of the first-first assembly wiring (321) and the plurality of bridge electrodes (322-2a to 322-2d) of the second-first assembly wiring (322) may have the largest DEP force.

Among the regions where a DEP force may be formed by an AC voltage applied to the protruding electrode (321-3) and the bridge electrodes (322-2a to 322-2d), the region between the protruding electrode (321-3) and the bridge electrodes (322-2a to 322-2d) may have the largest DEP force.

Since the first ring electrode (154-1) is disposed at the lower edge of the first semiconductor light emitting device (150-1), the first ring electrode (154-1) of the first semiconductor light emitting device (150-1) may be positioned in the gap region (G1) between the protruding electrode (321-3) of the first-first assembly wiring (321) and the plurality of bridge electrodes (322-2a to 322-2d) of the second-first assembly wiring (322). Accordingly, since the first semiconductor light emitting device (150-1), that is, the first ring electrode (154-1), is affected by the largest DEP force, the first semiconductor light emitting device (150-1) may be stably assembled into the first assembly hole (340H1) without shaking. In addition, since the plurality of bridge electrodes (322-2a to 322-2d) may be evenly arranged along the periphery of the first assembly hole (340H1), gap areas (G1) corresponding to the number of the plurality of bridge electrodes (322-2a to 322-2d) may be evenly formed at the edge of the first assembly hole (340H1). Accordingly, the first ring electrode (154-1) of the first semiconductor light emitting device (150-1) receives the largest DEP force formed in the plurality of gap areas (G1) evenly, so that the first semiconductor light emitting device (150-1) can be assembled into the first assembly hole (340H1) more quickly and stably.

### The Sub-Pixel (PX2)

In the sub-pixel (PX2), a pair of second assembly wirings, that is, the first-second assembly wiring (323) and the second-second assembly wiring (324), may be disposed on the substrate (310).

The first-second assembly wiring (323) may include a main electrode (323-1), a connection electrode (323-2), and a protruding electrode (323-3). The main electrode (323-1) may be arranged lengthwise along the second direction (Y). The main electrode (323-1) may be disposed to pass through a plurality of second sub-pixels (PX2) positioned along the second direction (Y). The connection electrode (323-2) may be disposed to extend from the main electrode (323-1) and be disposed in the second sub-pixel (PX2). The connection electrode (323-2) may be formed integrally with the main electrode (323-1), but is not limited thereto. The main electrode (323-1) and the connection electrode (323-2) may be formed simultaneously using the same patterning process, but is not limited thereto.

As illustrated in FIG. 8, the end of the connection electrode (323-2) may have a round shape in the second sub-pixel (PX2), but is not limited thereto.

The protruding electrode (323-3) may be disposed in the center area of the second assembly hole (340H2). The protruding electrode (323-3) may be placed on the first insulating layer (330). The protruding electrode (323-3) may penetrate the first insulating layer (330) and be connected to the connection electrode (323-2). The protruding electrode (323-3) may be vertically overlapped with the connection electrode (323-2). The protruding electrode (323-3) may be made of a different metal from the main electrode (323-1) or the connection electrode (323-2), but is not limited thereto. The protruding electrode (323-3) may be formed separately using a separate patterning process from the main electrode (323-1) or the connection electrode (323-2), but is not limited thereto.

Meanwhile, the second-second assembly wiring (324) may include a main electrode (324-1), a connection electrode (324-3), and a plurality of bridge electrodes (324-2a to 324-2d).

The main electrode (324-1) may be disposed lengthwise along the second direction (Y). The main electrode (324-1) may be disposed parallel to the main electrode (323-1) of the first-second assembly wiring (323) along the second direction (Y). The main electrode (324-1) may be disposed to pass through a plurality of second sub-pixels (PX2) positioned along the second direction (Y).

The connection electrode (324-3) may be extended from the main electrode (324-1) and arranged in the second sub-pixel (PX2). The connection electrode (324-3) may be formed integrally with the main electrode (324-1), but is not limited thereto. The main electrode (324-1) and the connection electrode (324-3) may be formed simultaneously using the same patterning process, but is not limited thereto. The connection electrode (324-3) may extend from the main electrode (324-1) and have a closed loop shape in the second sub-pixel (PX2). For example, one side of the connection electrode (324-3) may extend from the first region of the main electrode (324-1), the other side of the connection electrode (324-3) may extend from the second region of the main electrode (324-1), and one side of the connection electrode (324-3) and the other side of the connection electrode (324-3) may be disposed along the perimeter of the second assembly hole (340H2) in the second sub-pixel (PX2) and may meet each other.

A plurality of bridge electrodes (324-2a to 324-2d) may be branched from the main electrode (324-1). A plurality of bridge electrodes (324-2a to 324-2d) may be branched from the connection electrode (324-3). A plurality of bridge electrodes (324-2a to 324-2d) may extend from the connection electrode (324-3) toward the center of the second assembly hole (340H2). For example, when four bridge electrodes (324-2a to 324-2d) are provided, the four bridge electrodes (324-2a to 324-2d) may be disposed in directions of 45°, 135°, 225°, and 315° from the center of the second assembly hole (340H2), respectively. In this case, two bridge electrodes (324-2a, 324-2c) may be simultaneously connected to the main electrode (324-1) and the connection electrode (324-3), respectively, and two bridge electrodes (324-2b, 324-2d) may be connected to the connection electrode (324-3), respectively.

A through hole (H21) may be formed on the inner side of the connection electrode (324-3). In this case, the protruding electrode (323-3) of the first-second assembly wiring (323) may be positioned in the through hole (H21) of the connection electrode (324-3). The protruding electrode (323-3) of the first-second assembly wiring (323) may be surrounded by the connection electrode (324-3) or a plurality of bridge electrodes (324-2a to 324-2d). The protruding electrode (323-3) of the first-second assembly wiring (323) may be positioned in the through hole (H21) so as to be spaced apart from the plurality of bridge electrodes (324-2a to 324-2d). In this case, the plurality of bridge electrodes (324-2a to 324-2d) may be spaced apart from the protruding electrode (323-3) (323-3) of the first-second assembly wiring (323) by a predetermined gap area (G2).

Some areas of the plurality of bridge electrodes (324-2a to 324-2d) may vertically overlap with the second assembly hole (340H2). That is, a portion of each of the plurality of bridge electrodes (324-2a to 324-2d) may vertically overlap with the second assembly hole (340H2), and another portion of each of the plurality of bridge electrodes (324-2a to 324-2d) may be disposed on the outside of the second assembly hole (340H2).

The main electrode (324-1), the connection electrode (324-3), and the plurality of bridge electrodes (324-2a to 324-2d) may be formed integrally, but this is not limited. The main electrode (324-1), the connection electrode (324-3), and the plurality of bridge electrodes (324-2a to 324-2d) may be formed simultaneously using the same patterning process, but this is not limited.

The main electrode (324-1), the connection electrode (324-3), and the plurality of bridge electrodes (324-2a to 324-2d) may be disposed on the first insulating layer (330). The protruding electrode (323-3) of the first-second assembly wiring (323) may be disposed on the first insulating layer (330). Accordingly, the main electrode (324-1), the connection electrode (324-3), the plurality of bridge electrodes (324-2a to 324-2d), and the protruding electrode (323-3) of the first-second assembly wiring (323) may be disposed on the same layer.

As described above, the protruding electrode (323-3) of the first-second assembly wiring (323) may be positioned in the center area of the second assembly hole (340H2) and may be circular. In this case, the plurality of bridge electrodes (324-2a to 324-2d) may be horizontally spaced apart from the protruding electrode (323-3) of the first-second assembly wiring (323). For example, the plurality of bridge electrodes (324-2a to 324-2d) may be spaced apart from the protruding electrode (323-3) of the first-second assembly wiring (323) by a predetermined gap area (G2). The predetermined gap area (G2) may be formed at a position corresponding to the edge of the second assembly hole (340H2).

When the second semiconductor light emitting device (150-2) illustrated in FIG. 11 is placed in the second assembly hole (340H2), the second ring electrode (154-2) of the second semiconductor light emitting device (150-2) may be positioned in the gap region (G2) between the protruding electrode (323-3) of the first-second assembly wiring (323) and the plurality of bridge electrodes (324-2a to 324-2d) of the second-second assembly wiring (324). That is, the second ring electrode (154-2) of the second semiconductor light emitting device (150-2) may vertically overlap with the corresponding gap region (G2).

As illustrated in FIG. 15, a portion of each of the plurality of bridge electrodes (324-2a to 324-2d) of the second-second assembly wiring (324) may be positioned within the second assembly hole (340H2). That is, a portion of each of the plurality of bridge electrodes (324-2a to 324-2d) may vertically overlap with the second assembly hole (340H2). The protruding electrode (323-3) of the first-second assembly wiring (323) may be positioned in the central region of the second assembly hole (340H2). The plurality of bridge electrodes (324-2a to 324-2d) may be radially arranged around the second assembly hole (340H2). The plurality of bridge electrodes (324-2a to 324-2d) may be radially arranged around the protruding electrode (323-3) of the first-second assembly wiring (323). In this case, the plurality of bridge electrodes (324-2a to 324-2d) of the second-second assembly wiring (324) may be spaced apart from the protruding electrode (323-3) of the first-second assembly wiring (323) by a predetermined gap area (G2).

When the second semiconductor light emitting device (150-2) is assembled into the second assembly hole (340H2), the second ring electrode (154-2) of the second semiconductor light emitting device (150-2) may be positioned at the edge of the second assembly hole (340H2). The second ring electrode (154-2) of the second semiconductor light emitting device (150-2) may be positioned in a gap region (G2) between the protruding electrode (323-3) of the first-second assembly wiring (323) and the plurality of bridge electrodes (324-2a to 324-2d) of the second-second assembly wiring (324).

The inner diameter (D2-1) of the second ring electrode (154-2) of the second semiconductor light emitting device (150-2) may be larger than the diameter (D21) of the protruding electrode (323-3) of the first-second assembly wiring (323).

Although not illustrated, a portion of the second ring electrode (154-2) of the second semiconductor light emitting device (150-2) may vertically overlap with the protruding electrode (323-3) of the first-second assembly wiring (323), but this is not limited thereto.

Meanwhile, when an AC voltage is applied to the first-second assembly wiring (323) and the second-second assembly wiring (324), the DEP force may be formed to the greatest extent in the gap region (G2) between the protruding electrode (323-3) of the first-second assembly wiring (323) and the multiple bridge electrodes (324-2a to 324-2d) of the second-second assembly wiring (324). In this case, since the second ring electrode (154-2) is disposed at the lower edge of the second semiconductor light emitting device (150-2), the second ring electrode (154-2) of the second semiconductor light emitting device (150-2) may be positioned in the gap region (G2) between the protruding electrode (323-3) of the first-second assembly wiring (323) and the plurality of bridge electrodes (324-2a to 324-2d) of the second-second assembly wiring (324). Accordingly, since the second semiconductor light emitting device (150-2), that is, the second ring electrode (154-2), is affected by the largest DEP force, the second semiconductor light emitting device (150-2) may be stably assembled into the second assembly hole (340H2) without shaking. In addition, since the plurality of bridge electrodes (324-2a to 324-2d) may be evenly arranged along the periphery of the second assembly hole (340H2), gap regions (G2) corresponding to the number of the plurality of bridge electrodes (324-2a to 324-2d) may be evenly formed at the edge of the second assembly hole (340H2). Accordingly, the second ring electrode (154-2) of the second semiconductor light emitting device (150-2) receives the largest DEP force formed in the plurality of gap regions (G2) evenly, so that the second semiconductor light emitting device (150-2) can be assembled to the second assembly hole (340H2) more quickly and stably.

### The Sub-Pixel (PX3)

In the third sub-pixel (PX3), a pair of third assembly wirings, that is, the first-third assembly wiring (325) and the second-third assembly wiring (326), may be disposed on the substrate (310).

The first-third assembly wiring (325) may include a main electrode (325-1), a connection electrode (325-2), and a protruding electrode (325-3). The main electrode (325-1) may be disposed to be long along the second direction (Y). The main electrode (325-1) may be disposed to pass through a plurality of third sub-pixels (PX3) positioned along the second direction (Y). The connection electrode (325-2) may be extended from the main electrode (325-1) and arranged in the third sub-pixel (PX3). The connection electrode (325-2) may be formed integrally with the main electrode (325-1), but is not limited thereto. The main electrode (325-1) and the connection electrode (325-2) may be formed simultaneously using the same patterning process, but is not limited thereto.

As shown in FIG. 8, the end of the connection electrode (325-2) may have a round shape in the third sub-pixel (PX3), but is not limited thereto.

The protruding electrode (325-3) may be disposed in the center area of the third assembly hole (340H3). The protruding electrode (325-3) may be disposed on the first insulating layer (330). The protruding electrode (325-3) may be connected to the connection electrode (325-2) by penetrating the first insulating layer (330). The protruding electrode (325-3) may be vertically overlapped with the connecting electrode (325-2). The protruding electrode (325-3) may be made of a different metal from the main electrode (325-1) or the connecting electrode (325-2), but is not limited thereto. The protruding electrode (325-3) may be individually formed using a separate patterning process from the main electrode (325-1) or the connecting electrode (325-2), but is not limited thereto.

Meanwhile, the second-third assembly wiring (326) may include the main electrode (326-1), the connecting electrode (326-3), and a plurality of bridge electrodes (326-2a to 326-2d).

The main electrode (326-1) may be disposed lengthwise along the second direction (Y). The main electrode (326-1) may be disposed parallel to the main electrode (325-1) of the first-third assembly wiring (325) along the second direction (Y). The main electrode (326-1) may be disposed to pass through a plurality of third sub-pixels (PX3) positioned along the second direction (Y).

The connection electrode (326-3) may be extended from the main electrode (326-1) and may be arranged in the third sub-pixel (PX3). The connection electrode (326-3) may be formed integrally with the main electrode (326-1), but is not limited thereto. The main electrode (326-1) and the connection electrode (326-3) may be formed simultaneously using the same patterning process, but is not limited thereto. The connection electrode (326-3) may be extended from the main electrode (326-1) and may have a closed loop shape in the third sub-pixel (PX3). For example, one side of the connection electrode (326-3) extends from the first region of the main electrode (326-1), the other side of the connection electrode (326-3) extends from the second region of the main electrode (326-1), and one side of the connection electrode (326-3) and the other side of the connection electrode (326-3) are disposed along the perimeter of the third assembly hole (340H3) in the third sub-pixel (PX3) and can meet each other.

The plurality of bridge electrodes (326-2a to 326-2d) may be branched from the main electrode (326-1). The plurality of bridge electrodes (326-2a to 326-2d) may be branched from the connection electrode (326-3). The plurality of bridge electrodes (326-2a to 326-2d) may be extended from the connection electrode (326-3) toward the center of the third assembly hole (340H3). For example, when four bridge electrodes (326-2a to 326-2d) (326-2a to 326-2d) are provided, the four bridge electrodes (326-2a to 326-2d) (326-2a to 326-2d) may be disposed in directions of 45°, 135°, 225°, and 315° from the center of the third assembly hole (340H3), respectively. In this case, two bridge electrodes (326-2a, 326-2c) may be simultaneously connected to the main electrode (326-1) and the connection electrode (326-3), respectively, and two bridge electrodes (326-2b, 326-2d) may be simultaneously connected to the connection electrode (326-3), respectively.

A through hole (H31) may be formed on the inner side of the connecting electrode (326-3). In this case, the protruding electrode (325-3) of the first-third assembly wiring (325) may be positioned in the through hole (H31) of the connecting electrode (326-3). The protruding electrode (325-3) of the first-third assembly wiring (325) may be positioned in the through hole (H31) of the connecting electrode (326-3). The protruding electrode (325-3) of the first-third assembly wiring (325) may be surrounded by an electrode (326-3) or a plurality of bridge electrodes (326-2a to 326-2d). The protruding electrode (325-3) of the first-third assembly wiring (325) may be positioned in the through hole (H31) so as to be spaced apart from the plurality of bridge electrodes (326-2a to 326-2d). In this case, the plurality of bridge electrodes (326-2a to 326-2d) may be spaced apart from the protruding electrode (325-3) of the first-third assembly wiring (325) by a predetermined gap area (G3).

Some areas of the plurality of bridge electrodes (326-2a to 326-2d) may vertically overlap with the third assembly hole (340H3). That is, a portion of each of the plurality of bridge electrodes (326-2a to 326-2d) may vertically overlap with the third assembly hole (340H3), and another portion of each of the plurality of bridge electrodes (326-2a to 326-2d) may be disposed outside the third assembly hole (340H3).

The main electrode (326-1), the connection electrode (326-3), and the plurality of bridge electrodes (326-2a to 326-2d) may be formed integrally, but this is not limited. The main electrode (326-1), the connection electrode (326-3), and the plurality of bridge electrodes (326-2a to 326-2d) may be formed simultaneously using the same patterning process, but this is not limited.

The main electrode (326-1), the connection electrode (326-3), and the plurality of bridge electrodes (326-2a to 326-2d) may be disposed on the first insulating layer (330). The protruding electrode (325-3) of the first-third assembly wiring (325) may be disposed on the first insulating layer (330). Accordingly, the main electrode (326-1), the connection electrode (326-3), the plurality of bridge electrodes (326-2a to 326-2d), and the protruding electrode (325-3) of the first-third assembly wiring (325) may be disposed on the same layer.

As described above, the protruding electrode (325-3) of the first-third assembly wiring (325) may be positioned in the center area of the third assembly hole (340H3) and may be circular. In this case, the plurality of bridge electrodes (326-2a to 326-2d) may be horizontally spaced apart from the protruding electrode (325-3) of the first-third assembly wiring (325). For example, the plurality of bridge electrodes (326-2a to 326-2d) may be spaced apart from the protruding electrode (325-3) of the first-third assembly wiring (325) by a predetermined gap area (G3). The predetermined gap area (G3) may be formed at a position corresponding to the edge of the third assembly hole (340H3).

When the third semiconductor light emitting device (150-3) illustrated in FIG. 12 is placed in the third assembly hole (340H3), the plate electrode (154-3) of the third semiconductor light emitting device (150-3) may be positioned in the gap region (G3) between the protruding electrode (325-3) of the first-third assembly wiring (325) and the plurality of bridge electrodes (326-2a to 326-2d) of the second-third assembly wiring (326). That is, the plate electrode (154-3) of the third semiconductor light emitting device (150-3) may vertically overlap with the corresponding gap region (G3).

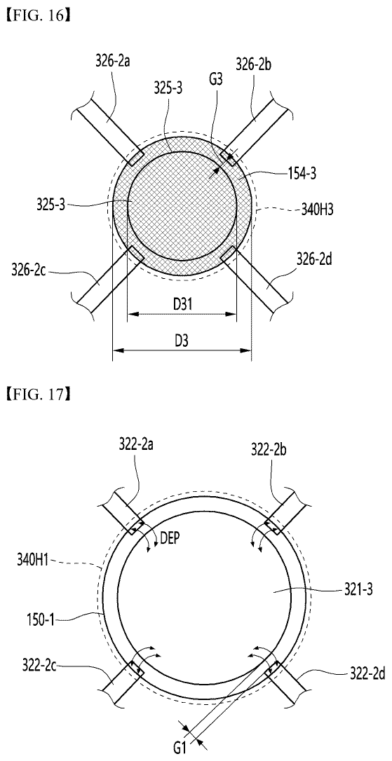

As illustrated in FIG. 16, a portion of each of the plurality of bridge electrodes (326-2a to 326-2d) of the second-third assembly wiring (326) may be positioned in the third assembly hole (340H3). That is, a portion of each of the plurality of bridge electrodes (326-2a to 326-2d) may vertically overlap with the third assembly hole (340H3). The protruding electrode (325-3) of the first-third assembly wiring (325) may be positioned at the center region of the third assembly hole (340H3). The plurality of bridge electrodes (326-2a to 326-2d) may be radially arranged with the third assembly hole (340H3) as the center. The plurality of bridge electrodes (326-2a to 326-2d) may be radially arranged with the protruding electrode (325-3) of the first-third assembly wiring (325) as the center. In this case, the plurality of bridge electrodes (326-2a to 326-2d) of the second-third assembly wiring (326) may be spaced apart from the protruding electrode (325-3) of the first-third assembly wiring (325) by a predetermined gap area (G3).

When the third semiconductor light emitting device (150-3) is assembled into the third assembly hole (340H3), the plate electrode (154-3) of the third semiconductor light emitting device (150-3) may be positioned at the edge of the third assembly hole (340H3). The plate electrode (154-3) of the third semiconductor light emitting device (150-3) may be positioned in the gap area (G2) between the protruding electrode (325-3) of the first-third assembly wiring (325) and the plurality of bridge electrodes (326-2a to 326-2d) of the second-third assembly wiring (326).

The diameter (D3) of the plate electrode (154-3) of the third semiconductor light emitting device (150-3) may be larger than the diameter (D31) of the protruding electrode (325-3) of the first-third assembly wiring (325).

Meanwhile, when an AC voltage is applied to the first-third assembly wiring (325) and the second-third assembly wiring (326), the DEP force may be formed to the greatest extent in the gap region (G3) between the protruding electrode (325-3) of the first-third assembly wiring (325) and the multiple bridge electrodes (326-2a to 326-2d) of the second-third assembly wiring (326). In this case, since the plate electrode (154-3) is disposed on the lower edge of the third semiconductor light emitting device (150-3), the plate electrode (154-3) of the third semiconductor light emitting device (150-3) may be positioned in the gap region (G3) between the protruding electrode (325-3) of the first-third assembly wiring (325) and the multiple bridge electrodes (326-2a to 326-2d) of the second-third assembly wiring (326). Accordingly, since the third semiconductor light emitting device (150-3), that is, the plate electrode (154-3), is affected by the largest DEP force, the third semiconductor light emitting device (150-3) may be stably assembled into the third assembly hole (340H3) without shaking. In addition, since the plurality of bridge electrodes (326-2a to 326-2d) may be evenly arranged along the periphery of the third assembly hole (340H3), gap areas (G3) corresponding to the number of the plurality of bridge electrodes (326-2a to 326-2d) may be evenly formed at the edge of the third assembly hole (340H3). Accordingly, the plate electrode (154-3) of the third semiconductor light emitting device (150-3) receives the largest DEP force formed in the plurality of gap areas (G3) evenly, so that the third semiconductor light emitting device (150-3) can be assembled to the third assembly hole (340H3) more quickly and stably.

As illustrated in FIG. 16, a portion of the plate electrode (154-3) of the third semiconductor light emitting device (150-3) may vertically overlap with each of the plurality of bridge electrodes (326-2a to 326-2d) of the second-third assembly wiring (326), but this is not limited thereto.

Meanwhile, a portion of each of the first ring electrode (154-1) of the first semiconductor light emitting device (150-1), the second ring electrode (154-2) of the second semiconductor light emitting device (150-2), and/or the plate electrode (154-3) of the third semiconductor light emitting device (150-3) may vertically overlap with each of the plurality of bridge electrodes (322-2a to 322-2d, 324-2a to 324-2d, 326-2a to 326-2d), but this is not limited thereto.

Meanwhile, as shown in FIG. 8 and FIG. 9, the first semiconductor light emitting device (150-1), the second semiconductor light emitting device (150-2) and the third semiconductor light emitting device (150-3) may have different sizes. For example, the size of the first semiconductor light emitting device (150-1) may be larger than the size of the second semiconductor light emitting device (150-2), and the size of the second semiconductor light emitting device (150-2) may be larger than the size of the third semiconductor light emitting device (150-3).

The shapes of the first assembly hole (340H1), the second assembly hole (340H2), and the third assembly hole (340H3) may correspond to the shapes of the first semiconductor light emitting device (150-1), the second semiconductor light emitting device (150-2), and the third semiconductor light emitting device (150-3), respectively. The size of the first assembly hole (340H1) may be larger than the size of the second assembly hole (340H2), and the size of the second assembly hole (340H2) may be larger than the size of the third assembly hole (340H3).

As described above, the shape of the protruding electrodes (321-3, 323-3, 325-3) of the first assembly wirings (321, 323, 325) of each of the first sub-pixel (PX1), the second sub-pixel (PX2), and the third sub-pixel (PX3) may correspond to the shape of each of the first assembly hole (340H1), the second assembly hole (340H2), and the third assembly hole (340H3).

The size of the protruding electrode (321-3) of the first-first assembly wiring (321) of the first sub-pixel (PX1) may be larger than the size of the protruding electrode (323-3) of the first-second assembly wiring (323) of the second sub-pixel (PX2). The size of the protruding electrode (323-3) of the first-second assembly wiring (323) of the second sub-pixel (PX2) may be larger than the size of the protruding electrode (325-3) of the first-third assembly wiring (325) of the third sub-pixel (PX3). In this case, the gap regions (G1, G2, G3) between the protruding electrodes (321-3, 323-3, 325-3) of the first assembly wiring (321, 323, 325) and the plurality of bridge electrodes (322-2a to 322-2d, 324-2a to 324-2d, 326-2a to 326-2a) of the second assembly wiring in each of the first sub-pixel (PX1), the second sub-pixel (PX2), and the third sub-pixel (PX3) may be different from each other, but are not limited thereto. The first gap region (G1) may be smaller than the second gap region (G2), and the second gap region (G2) may be smaller than the third gap region (G3).

The gap regions (G1, G2, G3) are identical to each other, and the AC voltage applied to a pair of assembly wirings (321 to 326) may be different in the first sub-pixel (PX1), the second sub-pixel (PX2), and the third sub-pixel (PX3). For example, the first AC voltage applied to a pair of first assembly wirings (321, 322) of the first sub-pixel (PX1) may be larger than the second AC voltage applied to a pair of second assembly wirings (323, 324) of the second sub-pixel (PX2), and the second AC voltage applied to a pair of second assembly wirings (323, 324) of the second sub-pixel (PX2) may be larger than the third AC voltage applied to a pair of third assembly wirings (325, 326) of the third sub-pixel (PX3).

According to the first embodiment, since the assembly holes (340H1, 340H2, 340H3) of multiple sub-pixels (PX1, PX2, PX3) are different, multiple semiconductor light emitting devices (150-1, 150-2, 150-3) can be assembled simultaneously without color mixing, thereby improving the assembly speed.

According to the first embodiment, a plurality of bridge electrodes (322-2a to 322-2d, 324-2a to 324-2d, 326-2a to 326-2d) of the second assembly wiring (322, 324, 326) may be disposed to surround the protruding electrode (321-3, 323-3, 325-3) and the protruding electrode (321-3, 323-3, 325-3) of the first assembly wiring (321, 323, 325). In this case, the DEP force may be formed to the greatest extent in each of the plurality of gap regions (G1, G2, G3) between the protruding electrodes (321-3, 323-3, 325-3) of the first assembly wiring (321, 323, 325) and the plurality of bridge electrodes (322-2a to 322-2d, 324-2a to 324-2d, 326-2a to 326-2d) of the second assembly wiring (322, 324, 326), so that the plurality of semiconductor light emitting devices (150-1, 150-2, 150-3) can be assembled more quickly without shaking, thereby reducing assembly defects.

Meanwhile, as illustrated in FIG. 17, when the first semiconductor light emitting device (150-1) is assembled into the first assembly hole (340H1) of the first sub-pixel (PX1), the first ring electrode (154-1) of the first semiconductor light emitting device (150)-1) may be positioned in the gap area (G1) between the protruding electrode (321-3) of the first assembly wiring and the plurality of bridge electrodes (322-2a to 322-3d) of the second-first assembly wiring (322), so that the first semiconductor light emitting device (150-1) may be quickly and stably assembled into the first assembly hole (340H1). In addition, since the first ring electrode (154-1) of the first semiconductor light emitting device (150-1) assembled in the first assembly hole (340H1) may be strongly fixed by the largest DEP force formed in the gap area (G1) between the protruding electrode (321-3) of the second-first assembly wiring (322) and the multiple bridge electrodes (322-2a to 322-3d) of the second-first assembly wiring (324), the first semiconductor light emitting device (150-1) may not fall out of the first assembly hole, thereby further reducing assembly defects.

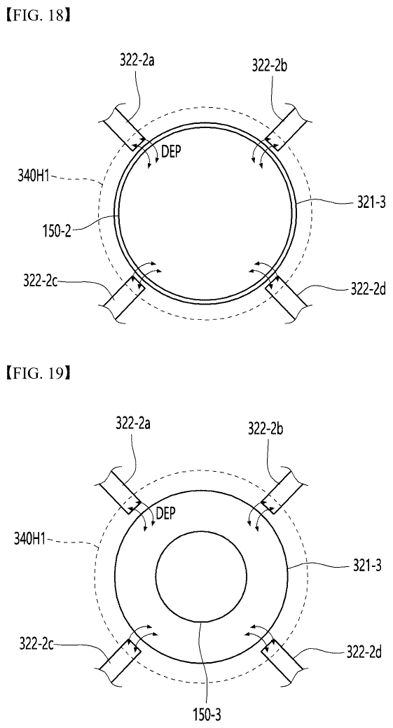

As illustrated in FIG. 18, when the second semiconductor light emitting device (150-2) is assembled into the first assembly hole (340H1) of the first sub-pixel (PX1), the second ring electrode (154-2) of the second semiconductor light emitting device (150-2) is not positioned in the gap region (G1) between the protruding electrode (321-3) of the second-first assembly wiring (322) and the multiple bridge electrodes (322-2a to 322-3d) of the second-first assembly wiring (324), so that the second semiconductor light emitting device (150-2) may not be assembled into the first assembly hole (340H1), thereby preventing color mixing defects.

That is, the outer diameter (D2-2) of the second ring electrode (154-2) of the second semiconductor light emitting device (150-2) is smaller than the diameter of the protruding electrode (321-3) of the second-first assembly wiring (322). Therefore, when the second semiconductor light emitting device (150-2) is placed in the center region of the first assembly hole (340H1), the second ring electrode (154-2) of the second semiconductor light emitting device (150-2) is not located in the gap region (G1) between the protruding electrode (321-3) of the second-first assembly wiring (322) and the plurality of bridge electrodes (322-2a to 322-3d) of the second-first assembly wiring (324).

In addition, when the second semiconductor light emitting device (150-2) is not placed in the center region of the first assembly hole (340H1), only a very small portion of the second ring electrode (154-2) of the second semiconductor light emitting device (150-2) is disposed in the gap region (G1) between the protruding electrode (321-3) of the second-first assembly wiring (322) and the plurality of bridge electrodes (322-2a to 322-3d) of the second-first assembly wiring (324), and the remainder is not located in the gap region (G1) between the protruding electrode (321-3) of the second-first assembly wiring (322) and the plurality of bridge electrodes (322-2a to 322-3d) of the second-first assembly wiring (324). Accordingly, since the second semiconductor light emitting device (150-2) has a weak fixing force due to the DEP force, the second semiconductor light emitting device (150-2) may be immediately removed from the first assembly hole (340H1) by the magnet, thereby preventing color mixing defects.

Meanwhile, as shown in FIG. 19, when the third semiconductor light emitting device (150-3) is assembled in the center area of the first assembly hole (340H1), the size of the third semiconductor light emitting device (150-3) is very small compared to the size of the first assembly hole (340H1), so the third semiconductor light emitting device (150-3) is far from the corresponding gap area (G1) and is not affected by the DEP force, so the third semiconductor light emitting device (150-3) may be removed from the first assembly hole (340H1), thereby preventing color mixing defects.

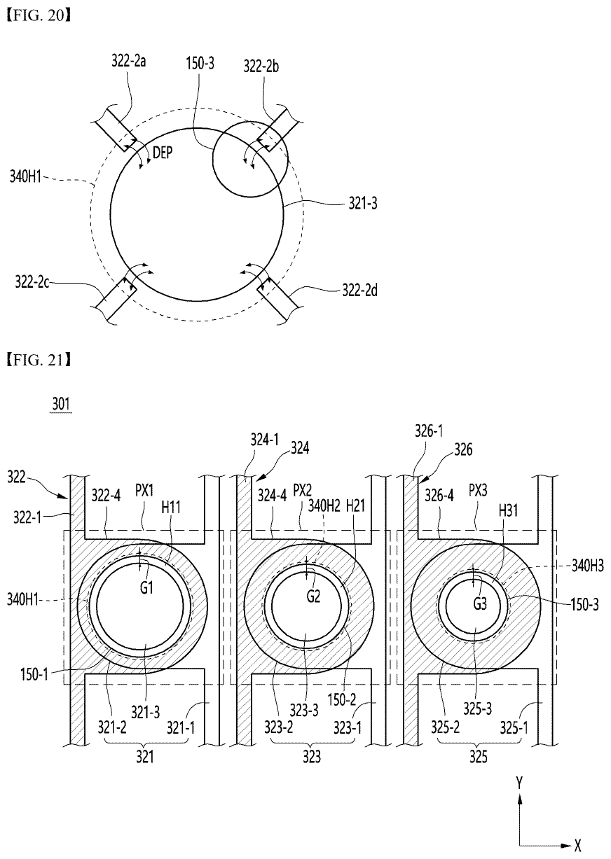

As illustrated in FIG. 20, when the third semiconductor light emitting device (150-3) is assembled on one of the gap regions (G1) of the plurality of gap regions (G1) at the edge of the first assembly hole (340H1), the third semiconductor light emitting device (150-3) is affected by the DEP force formed in one of the gap regions (G1) of the plurality of gap regions (G1) and thus has weak fixing force, thereby falling out of the first assembly hole (340H1), thereby preventing color mixing defects. In addition, since the DEP force formed in one of the gap regions (G1) of the plurality of gap regions (G1) of the third semiconductor light emitting device (150-3) may be formed non-uniformly, the third semiconductor light emitting device (150-3) shakes unstably due to the non-uniform DEP force, thereby easily falling out of the first assembly hole (340H1), thereby preventing color mixing defects.

Although not shown, if the third semiconductor light emitting device (150-3) is not located in any of the gap regions (G1) among the plurality of gap regions (G1) at the edge of the first assembly hole (340H1), the third semiconductor light emitting device (150-3) is not affected by the DEP force and thus falls out of the first assembly hole (340H1), thereby preventing color mixing defects.

According to the first embodiment, the lower electrodes of each of the plurality of semiconductor light emitting devices (150-1, 150-2, 150-3), that is, the first ring electrode (154-1), the second ring electrode (154-2), and the plate electrode (154-3), are positioned in the plurality of gap regions (G1, G2, G3) between the protruding electrodes (321-3, 323-3, 325-3) of the first assembly wiring (321, 323, 325) and the plurality of bridge electrodes (322-2a to 322-2d, 324-2a to 324-2d, 326-2a to 326-2d) of the second assembly wiring (322, 324, 326), thereby preventing color mixing defects.

Meanwhile, referring to FIG. 9 again, the second insulation layer (335) may be formed on the second assembly wiring (322, 324, 326). For example, the second insulation layer (335) may be formed on the protruding electrode (321-3, 323-3, 325-3) of the first assembly wiring (321, 323, 325) and the second assembly wiring (322, 324, 326).

The second insulation layer (335) can protect the protruding electrode (321-3, 323-3, 325-3) of the first assembly wiring (321, 323, 325) and the second assembly wiring (322, 324, 326). The upper surface of the second insulation layer (335) may be exposed by the assembly holes (340H1, 340H2, 340H3). If the second insulation layer (335) is omitted, during self-assembly, the second assembly wiring (322, 324, 326) may be corroded because the protruding electrode (321-3, 323-3, 325-3) of the first assembly wiring (321, 323, 325) and the second assembly wiring (322, 324, 326) come into contact with the fluid, or the protruding electrode (321-3, 323-3, 325-3) of the first assembly wiring (321, 323, 325) and the second assembly wiring (322, 324, 326) may be electrically short-circuited through the fluid.

The second insulating layer (335) can help to assemble the plurality of semiconductor light emitting devices (150-1, 150-2, 150-3) more easily. For this purpose, the second insulating layer (335) may be made of an insulating material having a dielectric constant. The intensity of the DEP force can vary not only by the dielectric constant of the second insulating layer (335) but also by the dielectric constant within the plurality of semiconductor light emitting devices (150-1, 150-2, 150-3), for example, by the dielectric constant of the passivation layer (157-1, 157-2, 157-3).

The partition wall (340) may be formed on the second insulating layer (335). By partially removing the partition wall (340), assembly holes (340H1, 340H2, 340H3) may be formed in each of the plurality of sub-pixels (PX1, PX2, PX3). The depth of the assembly holes (340H1, 340H2, 340H3) may be equal to or smaller than the thickness of the semiconductor light emitting device (150-1, 150-2 150-3), but is not limited thereto.

The third insulating layer (350) may be formed on the semiconductor light emitting device (150-1, 150-2 150-3) and the partition wall (340).

The third insulating layer (350) may be a planarization layer for easily forming the electrode wiring (360). The third insulating layer (350) may be a protective layer for protecting the semiconductor light emitting device (150-1, 150-2 150-3).

Although the third insulating layer (350) is depicted in the drawing as covering the upper side of the semiconductor light emitting device (150-1, 150-2 150-3), it may be formed only around the side of the semiconductor light emitting device (150-1, 150-2 150-3) and may not cover the upper side of the semiconductor light emitting device (150-1, 150-2 150-3). In this case, the contact hole process for removing the third insulating layer (350) formed on the upper side of the semiconductor light emitting device (150-1, 150-2 150-3) to form the electrode wiring (360) is not required, and the electrode wiring (360) may be directly connected to the upper side of the semiconductor light emitting device (150-1, 150-2 150-3), so that the process may be simplified and the process time may be shortened.

Since the third insulating layer (350) is to be formed relatively thick, it may be formed of an organic insulating material that is easy to form a thick thickness, but is not limited thereto.

The electrode wiring (360) may be disposed on the third insulating layer (350). The electrode wiring (360) may be connected to the upper side of the semiconductor light emitting device (150-1, 150-2 150-3) through the third insulating layer (350).

Meanwhile, the connecting electrode (370) can electrically connect the side of the semiconductor light emitting device (150-1, 150-2 150-3) and the second assembly wiring (322, 324, 326). For example, the connecting electrode (370) can electrically connect the lower electrode of the semiconductor light emitting device (150-1, 150-2 150-3). For example, the first ring electrode (154-1), the second ring electrode (154-2), and the plate electrode (154-3) may be connected to each side of the first ring electrode (154-1), the second ring electrode (154-2), and the plate electrode (154-3).

After the semiconductor light emitting device (150-1, 150-2 150-3) is assembled into the assembly hole (340H1, 340H2, 340H3), the connection electrode (360) may be formed. That is, a DEP force may be formed by an AC voltage applied to a pair of assembly wirings (321 to 326), and the semiconductor light emitting device (150-1, 150-2 150-3) can be assembled into the assembly hole (340H1, 340H2, 340H3) by this DEP force. Thereafter, the second insulating layer (335) may be removed so that the upper surface of a pair of assembly wirings (321 to 326) is exposed along the periphery of the semiconductor light emitting device (150-1, 150-2 150-3) within the assembly hole (340H1, 340H2, 340H3). Thereafter, a connection electrode (360) may be formed along the periphery of the semiconductor light emitting device (150-1, 150-2 150-3) within the assembly hole (340H1, 340H2, 340H3), so that the side of the semiconductor light emitting device (150-1, 150-2 150-3) and the second assembly wiring (322, 324, 326) may be electrically connected by the connection electrode (360).

In the display device (300) as described above, voltage is applied to the electrode wiring (360) and a pair of assembly wirings (321 to 326), so that different lights are emitted from the semiconductor light emitting device (150-1, 150-2, 150-3) and may be displayed as a color image.

### Second Embodiment

FIG. 21 illustrates a display device according to the second embodiment.

In the second embodiment, an auxiliary electrode (322-4, 324-4, 326-4) is adopted instead of the connecting electrodes (322-3, 324-3, 326-3) and the plurality of bridge electrodes (322-2a to 322-2d, 324-2a to 324-2d, 326-2a to 326-2d) of the first embodiment. In the second embodiment, components having the same shape, structure, and/or function as those in the first embodiment are given the same drawing reference numerals and detailed descriptions are omitted.

In the following description, drawing reference numerals not shown in FIG. 21 are shown in FIGS. 9 to 20.

Referring to FIG. 21, the display device (301) according to the second embodiment may include a plurality of sub-pixels (PX1, PX2, PX3). The plurality of sub-pixels (PX1, PX2, PX3) may configure a unit pixel (X) capable of playing a color image.

A plurality of semiconductor light emitting devices (150-1, 150-2, 150-3) may be disposed in each of the plurality of sub-pixels (PX1, PX2, PX3). The plurality of semiconductor light emitting devices (150-1, 150-2, 150-3) may emit different color light.

The plurality of semiconductor light emitting devices (150-1, 150-2, 150-3) may have a size of at least micrometers or less. Since the plurality of semiconductor light emitting devices (150-1, 150-2, 150-3) each have a very small size, it is difficult to mount the plurality of semiconductor light emitting devices (150-1, 150-2, 150-3) on the substrate (310).

According to an embodiment, the plurality of semiconductor light emitting devices (150-1, 150-2, 150-3) can be assembled on the substrate (310) using a self-assembly method.

For this purpose, a pair of assembly wirings (321 to 326) and assembly holes (340H1, 340H2, 340H3) may be disposed in each of a plurality of sub-pixels (PX1, PX2, PX3). For example, the first sub-pixel (PX1) may include a pair of first assembly wirings (321, 322) and a first assembly hole (340H1), the second sub-pixel (PX2) may include a pair of second assembly wirings (323, 324) and a second assembly hole (340H2), and the third sub-pixel (PX3) may include a pair of third assembly wirings (325, 326) and a third assembly hole (340H3).

A pair of assembly wirings (321 to 326) may include a pair of first assembly wirings (321, 322), a pair of second assembly wirings (323, 324), and a pair of third assembly wirings (325, 326). A pair of first assembly wirings may include a first-first assembly wiring (321) and a second-first assembly wiring (322). A pair of second assembly wirings may include a first-second assembly wiring (323) and a second-second assembly wiring (324). A pair of third assembly wirings may include a first-third assembly wiring (325) and a second-third assembly wiring (326).

The first assembly wiring, that is, each of the first-first assembly wiring (321), the first-second assembly wiring (323), and the first-third assembly wiring (325), may include a main electrode (321-1, 323-1, 325-1), a connection electrode (321-2, 323-2, 323-2), and a protruding electrode (321-3, 323-3, 325-3). Since the structures of these main electrodes (321-1, 323-1, 325-1), connection electrodes (321-2, 323-2, 323-2), and protruding electrodes (321-3, 323-3, 325-3) have been described in the first embodiment, a detailed description thereof will be omitted.

The second assembly wiring, that is, each of the second-first assembly wiring (322), the second-second assembly wiring (324), and the second-third assembly wiring (326), may include a main electrode (322-1, 324-1, 326-1) and an auxiliary electrode (322-4, 324-4, 326-4). Since the structure of the main electrodes (322-1, 324-1, 326-1) has been described in the first embodiment, a detailed description thereof will be omitted.

The auxiliary electrodes (322-4, 324-4, 326-4) may extend from the main electrodes (322-1, 324-1, 326-1) and be disposed in sub-pixels (PX1, PX2, PX3).

Each auxiliary electrodes (322-4, 324-4, 326-4) may include a through hole (H11, H121, H31). The through hole (H11, H121, H31) may be a hole that penetrates the upper and lower surfaces of each auxiliary electrode (322-4, 324-4, 326-4) from the center of the auxiliary electrode (322-4, 324-4, 326-4).

Each auxiliary electrode (322-4, 324-4, 326-4) may have a ring shape or a closed loop shape due to the through hole (H11, H121, H31). The shape of the through hole (H11, H121, H31) may correspond to the shape of the assembly hole (340H1, 340H2, 340H3). For example, if the assembly holes (340H1, 340H2, 340H3) are circular when viewed from above, the through holes (H11, H121, H31) may also be circular.

Some areas of the auxiliary electrodes (322-4, 324-4, 326-4) may vertically overlap the assembly holes (340H1, 340H2, 340H3).

The protruding electrodes (321-3, 323-3, 325-3) of the first assembly wiring (321, 323, 325) may be placed in the through holes (H11, H121, H31). The protruding electrode (321-3, 323-3, 325-3) may be placed in the center area of the assembly hole (340H1, 340H2, 340H3). The auxiliary electrode (322-4, 324-4, 326-4) may surround the protruding electrode (321-3, 323-3, 325-3).

The protruding electrode (321-3, 323-3, 325-3) and the auxiliary electrode (322-4, 324-4, 326-4) may be placed on the same layer, that is, on the first insulating layer (330). In this case, the auxiliary electrode (322-4, 324-4, 326-4) and the protruding electrode (321-3, 323-3, 325-3) may be horizontally spaced apart. For example, the auxiliary electrode (322-4, 324-4, 326-4) may be horizontally spaced apart from the protruding electrode (321-3, 323-3, 325-3) along the perimeter of the protruding electrode (321-3, 323-3, 325-3). For example, the auxiliary electrode (322-4, 324-4, 326-4) may be spaced apart from the protruding electrode (321-3, 323-3, 325-3) along the perimeter of the protruding electrode (321-3, 323-3, 325-3) by a predetermined gap area (G1, G2, G3). The gap area (G1, G2, G3) may be constant along the perimeter of the protruding electrode (321-3, 323-3, 325-3), but is not limited thereto.

Meanwhile, a semiconductor light emitting device (150-1, 150-2, 150-3) can be assembled into the assembly hole (340H1, 340H2, 340H3) by using the DEP force formed by a pair of assembly wirings (321 to 326). When the semiconductor light emitting device (150-1, 150-2, 150-3) is assembled into the assembly hole (340H1, 340H2, 340H3), the lower electrode of the semiconductor light emitting device (150-1, 150-2, 150-3), that is, the first ring electrode (154-1), the second ring electrode (154-2), and the plate electrode (154-3) may be positioned in the corresponding gap region (G1, G2, G3).

The first ring electrode (154-1), the second ring electrode (154-2), or the plate electrode (154-3) of the semiconductor light emitting device (150-1, 150-2, 150-3) may be designed to be positioned corresponding to the corresponding gap region (G1, G2, G3) where the DEP force may be formed the largest. Accordingly, the first ring electrode (154-1), the second ring electrode (154-2), or the plate electrode (154-3) of the semiconductor light emitting device (150-1, 150-2, 150-3) can be strongly pulled by the largest DEP force formed in the corresponding gap region (G1, G2, G3), so that the semiconductor light emitting device (150-1, 150-2, 150-3) may be quickly assembled into the assembly hole (340H1, 340H2, 340H3).

In addition, a gap area (G1, G2, G3) may be formed between the auxiliary electrode (322-4, 324-4, 326-4) and the protruding electrode (321-3, 323-3, 325-3) along the edge of the assembly hole (340H1, 340H2, 340H3), so that the lower edge of the semiconductor light emitting device (150-1, 150-2, 150-3) is evenly and strongly pulled by the largest DEP force formed along the edge of the assembly hole (340H1, 340H2, 340H3), so that the semiconductor light emitting device (150-1, 150-2, 150-3) may be stably assembled into the assembly hole (340H1, 340H2, 340H3) without shaking.

Meanwhile, although not shown, some areas of the first ring electrode (154-1), the second ring electrode (154-2), and/or the plate electrode (154-3) of the semiconductor light emitting device (150-1, 150-2, 150-3) may vertically overlap with the auxiliary electrode (322-4, 324-4, 326-4), but this is not limited thereto.

Meanwhile, the display device described above may be a display panel. That is, in the embodiment, the display device and the display panel may be understood to have the same meaning. In the embodiment, the display device in a practical sense may include a display panel and a controller (or processor) capable of controlling the display panel to display an image.

The above detailed description should not be construed as limiting in all aspects and should be considered as illustrative. The scope of the embodiment should be determined by a reasonable interpretation of the appended claims, and all changes within the equivalent scope of the embodiment are included in the scope of the embodiment.

### Industrial Applicability

The embodiment may be adopted in the field of displays that display images or information. The embodiment may be adopted in the field of displays that display images or information using a semiconductor light emitting device. The semiconductor light emitting device may be a micro-level semiconductor light emitting device or a nano-level semiconductor light emitting device.

For example, the embodiment may be adopted in a TV, a signage, a smart phone, a mobile phone, a mobile terminal, a HUD for a car, a backlight unit for a laptop, a display device for VR or AR.

1. A display device, comprising:
a first sub-pixel including a pair of first assembly wirings, a first assembly hole, and a first semiconductor light emitting device in the first assembly hole;
a second sub-pixel including a pair of second assembly wirings, a second assembly hole, and a second semiconductor light emitting device in the second assembly hole; and
a third sub-pixel including a pair of third assembly wirings, a third assembly hole, and a third semiconductor light emitting device in the third assembly hole;
wherein the first assembly hole, the second assembly hole, and the third assembly hole have different sizes from each other,
wherein the first semiconductor light emitting device comprises a first ring electrode;
wherein the first pair of first assembly wirings comprise a first-first assembly wiring and a first-second assembly wiring having a first gap area at an edge of the first assembly hole,
wherein the first ring electrode of the first semiconductor light emitting device is disposed in the first gap area,
wherein the second pair of second assembly wirings comprise a second-first assembly wiring and a second-second assembly wiring having a second gap area at an edge of the second assembly hole,
wherein the pair of third assembly wirings comprises a third-first assembly wiring and a third-second assembly wiring having a third gap region at an edge of the third assembly hole, and
wherein each of the first-first assembly wiring, the second-first assembly wiring, and the third-first assembly wiring comprises a main electrode and a protruding electrode projected upward from the main electrode.

2. The display device according to claim 1, wherein the second semiconductor light emitting device comprises a second ring electrode, and
wherein the second ring electrode of the second semiconductor light emitting device is disposed in the second gap area.

3. The display device according to claim 2, wherein an outer diameter of the first ring electrode is larger than that of the second ring electrode.

4. The display device according to claim 2, wherein the third semiconductor light emitting device comprises a plate electrode, and
wherein the plate electrode of the third semiconductor light emitting device is disposed in the third gap region.

5. The display device according to claim 4, wherein a diameter of the plate electrode is smaller than an inner diameter of the second ring electrode.

6. The display device according to claim 4, wherein the first ring electrode, the second ring electrode, and the plate electrode are not vertically overlapped each other.

7. (canceled)

8. A display device, comprising:
a first sub-pixel including a pair of first assembly wirings, a first assembly hole, and a first semiconductor light emitting device in the first assembly hole;
a second sub-pixel including a pair of second assembly wirings, a second assembly hole, and a second semiconductor light emitting device in the second assembly hole; and
a third sub-pixel including a pair of third assembly wirings, a third assembly hole, and a third semiconductor light emitting device in the third assembly hole;
wherein the first assembly hole, the second assembly hole, and the third assembly hole have different sizes from each other,
wherein the first semiconductor light emitting device comprises a first ring electrode;
wherein the first pair of first assembly wirings comprise a first-first assembly wiring and a first-second assembly wiring having a first gap area at an edge of the first assembly hole,
wherein the first ring electrode of the first semiconductor light emitting device is disposed in the first gap area,
wherein the second pair of second assembly wirings comprise a second-first assembly wiring and a second-second assembly wiring having a second gap area at an edge of the second assembly hole,
wherein the pair of third assembly wirings comprises a third-first assembly wiring and a third-second assembly wiring having a third gap region at an edge of the third assembly hole,
wherein each of the first-second assembly wiring, the second-second assembly wiring, and the third-second assembly respectively comprises a main electrode and a plurality of bridge electrodes branching from the main electrode;
wherein the protruding electrode and the plurality of bridge electrodes are disposed on a same layer,
wherein the protruding electrode of the first-first assembly wiring is disposed in a center area of the first assembly hole, and
wherein the plurality of bridge electrodes of the first-second assembly wiring are disposed radially around the protruding electrode.

9. The display device according to claim 8, wherein the first gap region comprises a plurality of first gap regions,
wherein the protruding electrode of the first-first assembly wiring and the plurality of bridge electrodes of the first-second assembly wiring have the plurality of gap regions, and
wherein the first ring electrode of the first semiconductor light emitting device is disposed in the plurality of first gap regions.

10. The display device according to claim 9, wherein the second gap region comprises a plurality of second gap regions,
wherein the protruding electrode of the second-first assembly wiring and the plurality of bridge electrodes of the second-second assembly wiring have the plurality of second gap regions, and
wherein the second ring electrode of the second semiconductor light emitting device is disposed in the plurality of second gap regions.

11. The display device according to claim 10, wherein the third gap region comprises a plurality of third gap regions,
wherein the protruding electrode of the third-first assembly wiring and the plurality of bridge electrodes of the third-second assembly wiring have the plurality of third gap regions, and
wherein an edge of the plate electrode of the third semiconductor light emitting device is disposed in the plurality of third gap regions.

12. The display device according to claim 8, wherein a portion of the plate electrode is configured to vertically overlap each of the plurality of bridge electrodes.

13. A display device, comprising:
a first sub-pixel including a pair of first assembly wirings, a first assembly hole, and a first semiconductor light emitting device in the first assembly hole;
a second sub-pixel including a pair of second assembly wirings, a second assembly hole, and a second semiconductor light emitting device in the second assembly hole; and
a third sub-pixel including a pair of third assembly wirings, a third assembly hole, and a third semiconductor light emitting device in the third assembly hole;
wherein the first assembly hole, the second assembly hole, and the third assembly hole have different sizes from each other,
wherein the first semiconductor light emitting device comprises a first ring electrode;
wherein the first pair of first assembly wirings comprise a first-first assembly wiring and a first-second assembly wiring having a first gap area at an edge of the first assembly hole,
wherein the first ring electrode of the first semiconductor light emitting device is disposed in the first gap area,
wherein the second pair of second assembly wirings comprise a second-first assembly wiring and a second-second assembly wiring having a second gap area at an edge of the second assembly hole,
wherein the pair of third assembly wirings comprises a third-first assembly wiring and a third-second assembly wiring having a third gap region at an edge of the third assembly hole,
wherein each of the first-second assembly wiring, the second-second assembly wiring, and the third-second assembly wiring comprises a main electrode and an auxiliary electrode extended from the main electrode,
wherein the protruding electrode and the auxiliary electrode are disposed on a same layer,
wherein the protruding electrode is disposed in a central region of each of the first assembly hole, the second assembly hole, and the third assembly hole, and
wherein the auxiliary electrode is configured to surround the protruding electrode.

14. The display device according to claim 13, wherein the auxiliary electrode comprises a through hole; and
wherein the protruding electrode is disposed in the through hole.

15. The display device according to claim 13, wherein the protruding electrode of the first-first assembly wiring and the auxiliary electrode of the first-second assembly wiring have the first gap region, and
wherein the first ring electrode of the first semiconductor light emitting device is disposed in the first gap region.

16. The display device according to claim 15, wherein the protruding electrode of the second-first assembly wiring and the auxiliary electrode of the second-second assembly wiring have the second gap region, and
wherein the second ring electrode of the second semiconductor light emitting device is disposed in the second gap region.

17. The display device according to claim 16, wherein the protruding electrode of the third-first assembly wiring and the auxiliary electrode of the third-second assembly wiring have the third gap region, and
wherein an edge of the plate electrode of the third semiconductor light emitting device is disposed in the third gap region.

18. The display device according to claim 1, wherein an inner diameter of the first ring electrode is larger than a diameter of the protruding electrode of the first-first assembly wiring, and
wherein an inner diameter of the second ring electrode is larger than a diameter of the protruding electrode of the second-first assembly wiring.

19. The display device according to claim 1, wherein a diameter of the plate electrode is larger than that of the protruding electrode of the third-first assembly wiring.

20. The display device according to claim 1, further comprising:
a connection electrode surrounding the first semiconductor light emitting device, the second semiconductor light emitting device, and the third semiconductor light emitting device in each of the first assembly hole, the second assembly hole, and the third assembly hole; and
an electrode wiring on an upper side of each of the first semiconductor light emitting device, the second semiconductor light emitting device, and the third semiconductor light emitting device;
wherein the connection electrode is connected to at least one assembly wiring among each of the pair of first assembly wirings, the pair of second assembly wirings, and the pair of third assembly wirings.
